(19) United States
(12) Patent Application Publication
(10) Pub. No.: US 2026/0194569 A1
(43) Pub. Date: Jul. 9, 2026

(54) SYSTEM AND METHOD OF PARTIAL DISCHARGE DETECTION USING ULTRASOUND BASED ON OPTIMIZED DEEP LEARNING APPROACH

(71) Applicant: KING FAHD UNIVERSITY OF PETROLEUM AND MINERALS, Dhahran (SA)

(72) Inventors: Abdulaziz Hamoud ALSHALAWI, Riyadh (SA); Fahad Saleh ALISMAIL, Dhahran (SA)

(73) Assignee: KING FAHD UNIVERSITY OF PETROLEUM AND MINERALS, Dhahran (SA)

(21) Appl. No.: 19/177,441

(22) Filed: Apr. 11, 2025

Related U.S. Application Data
(60) Provisional application No. 63/741,731, filed on Jan. 3, 2025.

(51) Int. Cl. G01R 31/14; G01R 31/12

(52) U.S. Cl. CPC G01R 31/14; G01R 31/1209; G01R 31/1272

(57) ABSTRACT

A method for classifying Partial Discharge (PD) in an electrical equipment includes detecting a mechanical wave produced by an electrical discharge event using an acoustic emission sensor. Further, the detected mechanical wave is converted into an audio signal. Upon conversion, a waveform of the audio signal is determined, and the determined waveform is converted into a waveform image. Once the determined waveform is converted into the waveform image, a fault class among four different PD types is predicted based on the waveform image using a Convolution Neural Network (CNN). Further, an indication of the fault class of the electrical equipment is provided as an output to a user.

### CROSS-REFERENCE TO RELATED APPLICATIONS

This application claims the benefit of priority to provisional application No. 63/741,731 filed Jan. 3, 2025, the entire contents of which are incorporated herein by reference.

### STATEMENT REGARDING PRIOR DISCLOSURE BY THE INVENTORS

Aspects of this technology are described in an article A. H. Alshalawi and F. S. Al-Ismail, “Partial Discharge Detection Based on Ultrasound Using Optimized Deep Learning Approach,” in IEEE Access, vol. 12, pp. 5151-5162, 2024 (2024), and is herein incorporated by reference in its entirety.

### STATEMENT OF ACKNOWLEDGEMENT

The support provided by the Deanship of Scientific Research (DSR) at King Fahd University of Petroleum & Minerals (KFUPM), Dhahran, Saudi Arabia, is gratefully acknowledged.

### BACKGROUND

### Technical Field

The present disclosure is directed to fault detection in electrical equipment, and more particularly to a method and a system for detecting and classifying Partial Discharge (PD) in an electrical equipment.

### Description of Related Art

The “background” description provided herein is for the purpose of generally presenting the context of the disclosure. Work of the presently named inventors, to the extent it is described in this background section, as well as aspects of the description which may not otherwise qualify as prior art at the time of filing, are neither expressly or impliedly admitted as prior art against the present invention.

Partial Discharge (PD) refers to a localized electrical discharge that occurs within insulating materials due to imperfections such as voids, cracks, or gas bubbles. These flaws create regions where the electric field intensity is significantly higher than in the surrounding insulation. This localized electrical stress can accumulate over time, leading to the degradation of the insulation material and, eventually, the failure of electrical equipment. Such failures can result in severe malfunctions and costly repairs.

PD can affect a wide range of electrical equipment that employs various insulation types, including gas-insulated, oil-insulated, and solid-insulated devices. Common causes of PD include aging, manufacturing defects, improper installation, and external stressors. Specific factors contributing to PD include excessive electric fields triggering discharges in weak spots, aging reducing the insulating effectiveness of materials, localized overheating creating voids or gas bubbles, impurities or defects introduced during production, and faulty terminations or improper assembly accelerating breakdown.

According to the International Electrotechnical Commission (IEC) 60270 standard, PD manifests in various forms, including corona discharge, surface discharge, and internal discharge. Corona discharge occurs in gaseous environments due to air ionization near high-voltage electrodes. Surface discharge takes place along dielectric material surfaces, often at the interface of a conductor and insulation. Internal discharge happens within insulation material due to cracks, contamination, or voids, resulting in localized electrical breakdown.

Traditional methods for detecting and measuring PD, based on IEC 60270, involve measuring the apparent charge (q) at the terminals of electrical equipment. While effective in controlled environments where variables such as temperature, humidity, and electromagnetic interference are stable, these methods face significant limitations in real-world applications. Environmental noise, fluctuating conditions, and external interference can complicate real-time PD detection and monitoring.

Electrical equipment, particularly in critical infrastructure, is vulnerable to a spectrum of faults. While some issues, like loose wiring, may be minor and inexpensive to address, insulation breakdown due to PD can lead to severe problems such as tracking discharges. These can result in substantial maintenance costs or necessitate equipment replacement.

Early detection and monitoring of PD are crucial to preventing catastrophic failures, reducing operational downtime, and minimizing repair costs. To overcome the limitations of traditional methods, advanced techniques that enable real-time monitoring, detection, and analysis of PD in operational environments are essential. These novel approaches can ensure more reliable and efficient equipment maintenance strategies.

Accordingly, it is an object of the present disclosure to provide a method and a system for detecting and classifying the PD in the electrical equipment.

### SUMMARY

In an exemplary embodiment, a portable system for inspecting an electrical equipment for Partial Discharge (PD) is described. The system includes an acoustic emission sensor for detecting a mechanical wave produced by an electrical discharge event and converting the mechanical wave into an audio signal. The system includes a signal preprocessing unit to determine a waveform of the audio signal and converting the determined waveform into a waveform image. The converting includes performing a Short-Time Fourier Transform (STFT) on the audio signal to preserve time information and further to convert the audio signal into a spectrogram as the waveform image. The system includes a processing circuitry configured with a Convolution Neural Network (CNN) that takes as input the waveform image and outputs a fault class among four different PD types, which are an arcing, a corona discharge, a tracking, a looseness, as well as a healthy equipment. The system includes an output device for outputting an indication of the fault class for the electrical equipment.

In another exemplary embodiment, a method for classifying Partial Discharge (PD) in an electrical equipment is described. The method includes detecting, by an acoustic emission sensor, a mechanical wave produced by an electrical discharge event and converting the mechanical wave into an audio signal. The method includes determining, by a signal preprocessing unit, a waveform of the audio signal and converting the determined waveform into a waveform image. The converting includes performing a Short-Time Fourier Transform (STFT) on the audio signal to preserve time information and further to convert the audio signal into a spectrogram as the waveform image. The method includes predicting, by a processing circuitry configured with a Convolution Neural Network (CNN) that takes as input the waveform image, a fault class among four different PD types, which are an arcing, a corona discharge, a tracking, a looseness, as well as a healthy equipment. The method includes outputting, by an output device, an indication of the fault class of the electrical equipment.

In another exemplary embodiment, a non-transitory computer-readable medium having instructions stored therein that, when executed by one or more processors, cause the one or more processors to perform a method for classifying Partial Discharge (PD) in an electrical equipment. The method includes detecting, by an acoustic emission sensor, a mechanical wave produced by an electrical discharge event and converting the mechanical wave into an audio signal. The method includes determining, by a signal preprocessing unit, a waveform of the audio signal and converting the determined waveform into a waveform image. The converting includes performing a Short-Time Fourier Transform (STFT) on the audio signal to preserve time information and further to convert the audio signal into a spectrogram as the waveform image. The method includes predicting, by a processing circuitry configured with a Convolution Neural Network (CNN) that takes as input the waveform image, a fault class among four different PD types, which are an arcing, a corona discharge, a tracking, a looseness, as well as a healthy equipment. The method includes outputting, by an output device, an indication of the fault class of the electrical equipment.

The foregoing general description of the illustrative embodiments and the following detailed description thereof are merely exemplary aspects of the teachings of this disclosure and are not restrictive.

### BRIEF DESCRIPTION OF THE DRAWINGS

A more complete appreciation of this disclosure and many of the attendant advantages thereof will be readily obtained as the same becomes better understood by reference to the following detailed description when considered in connection with the accompanying drawings, wherein:

FIG. 1 is an exemplary diagram of a portable system configured for inspecting an electrical equipment for Partial Discharge (PD), according to certain embodiments.

FIG. 2 is an exemplary diagram representing various types of PD, according to certain embodiments.

FIG. 3 is an exemplary diagram representing various types of PD detection methods, according to certain embodiments.

FIG. 4A-FIG. 4B is an exemplary diagram representing PD models, according to certain embodiments.

FIG. 5 is an exemplary diagram representing a basic behavior of piezoelectric ceramics, according to certain embodiments.

FIG. 6 is an exemplary diagram representing a working principle of the portable system, according to certain embodiments.

FIG. 7 is an exemplary diagram representing a modern PD detector circuit, according to certain embodiments.

FIG. 8 is an exemplary diagram representing time-series waveforms of random audio signal waveform samples, according to certain embodiments.

FIG. 9 is an exemplary diagram representing a common waveform pattern of an arcing, according to certain embodiments.

FIG. 10 is an exemplary diagram representing a common waveform pattern of a looseness, according to certain embodiments.

FIG. 11 is an exemplary diagram representing a common waveform pattern of a corona discharge, according to certain embodiments.

FIG. 12 is an exemplary diagram representing a common waveform pattern of a tracking, according to certain embodiments.

FIG. 13 is an exemplary diagram representing an implementation of a Short-Time Fourier Transform (STFT) on audio signals, according to certain embodiments.

FIG. 14 is an exemplary diagram representing a general architecture of a Convolution Neural Network (CNN), according to certain embodiments.

FIG. 15 is an exemplary diagram depicting a CNN architecture for a single-phase method, according to certain embodiments.

FIG. 16 is an exemplary diagram representing a pictorial representation of features detection performed by convolution layers of the CNN, according to certain embodiments.

FIG. 17 is an exemplary diagram representing a confusion matrix generated for the CNN operating on the single-phase method, according to certain embodiments.

FIG. 18 is an exemplary diagram representing training versus validation graphs generated for the CNN operating on the single-phase method, according to certain embodiments.

FIG. 19 is an exemplary diagram representing training versus validation graphs generated for the CNN operating on a double-phase method, according to certain embodiments.

FIG. 20 is an exemplary diagram representing a confusion matrix generated for a first phase of the CNN operating on the double-phase method, according to certain embodiments.

FIG. 21 is an exemplary diagram representing a graph depicting a progress of an objective function applied to the CNN operating on the single-phase method, according to certain embodiments.

FIG. 22 is an exemplary diagram representing a confusion matrix generated by the CNN operating on the single-phase method after applying the objective function, according to certain embodiments.

FIG. 23 is an exemplary diagram representing a bar graph depicting experimental results of various existing pre-trained models with disclosed CNN models, according to certain embodiments.

FIG. 24 is an exemplary diagram depicting a flowchart of a method of classifying the PD in the electrical equipment, according to certain embodiments.

FIG. 25 is an illustration of a non-limiting example of details of computing hardware used in the portable system, according to certain embodiments.

FIG. 26 is an exemplary schematic diagram of a data processing system used within the portable system, according to certain embodiments.

FIG. 27 is an exemplary schematic diagram of a processor used with the portable system, according to certain embodiments.

FIG. 28 is an illustration of a non-limiting example of distributed components which may share processing with the controller, according to certain embodiments.

### DETAILED DESCRIPTION

In the drawings, like reference numerals designate identical or corresponding parts throughout the several views. Further, as used herein, the words “a,” “an” and the like generally carry a meaning of “one or more,” unless stated otherwise.

Furthermore, the terms “approximately,” “approximate,” “about,” and similar terms generally refer to ranges that include the identified value within a margin of 20%, 10%, or preferably 5%, and any values there between.

Aspects of this disclosure are directed to a system, device, and method for classifying Partial Discharge (PD) in electrical equipment. The method includes detecting a mechanical wave produced by an electrical discharge event using an acoustic emission sensor. Further, the detected mechanical wave is converted into an audio signal. Upon conversion, a waveform of the audio signal is determined, and the determined waveform is converted into a waveform image. Once the determined waveform is converted into the waveform image, a fault class among four different PD types is predicted based on the waveform image using a Convolution Neural Network (CNN). Further, an indication of the fault class of the electrical equipment is provided as an output to a user (e.g., a maintenance manager, a safety and compliance officer, and the like).

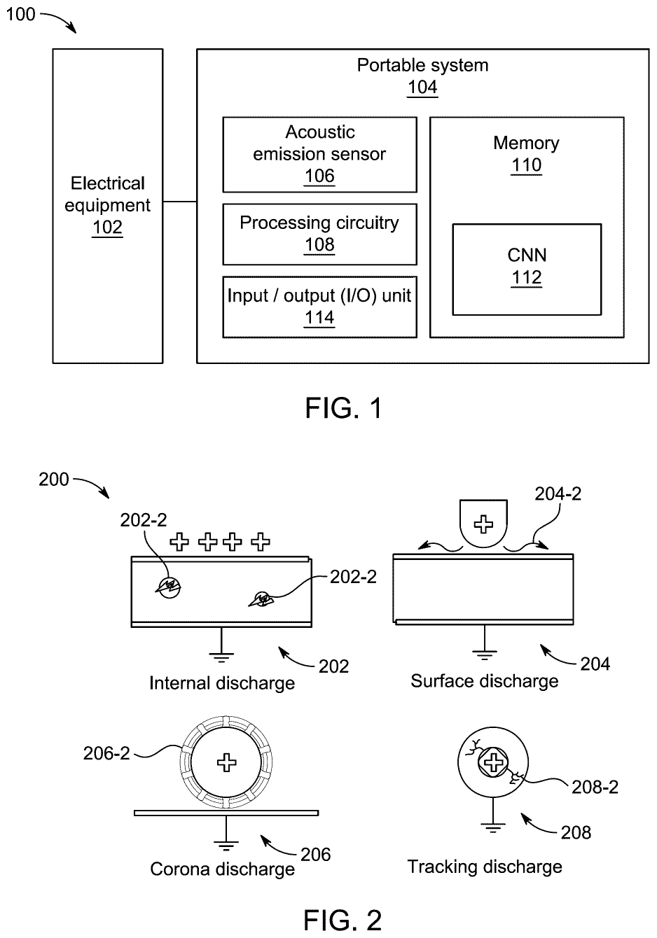

Referring now to FIG. 1, the present disclosure provides an exemplary diagram 100 of a portable system 104 configured for inspecting an electrical equipment for Partial Discharge (PD), according to certain embodiments. The electrical equipment may correspond to an electrical equipment 102. In particular, the portable system 104 may be configured to detect the PD in the electrical equipment 102. In an embodiment, the PD in the electrical equipment 102 refers to a localized electrical discharge or a sparking that occurs within an insulating material (i.e., insulation) of the electrical equipment 102. The PD in the electrical equipment 102 is caused by a presence of a void, a crack, or a gas bubble within the insulating material. The insulating material in the electrical equipment 102 is used to prevent an unwanted flow of electrical current, ensuring safety by protecting against electric shock and short circuits. The insulating material also helps in maintaining efficient operation by reducing energy losses and electrical interference. Examples of the electrical equipment 102 may include, but are not limited to, a transformer, a Gas-Insulated Switchgear (GIS), a circuit breaker, a capacitor, and a cable. Further, the insulating material may be, for example, a rubber, a Polyethylene (PE), a Polyvinyl Chloride (PVC), an epoxy resin, a glass, a polyimide, and the like.

In order to inspect the electrical equipment 102 for the PD, the portable system 104 may include an acoustic emission sensor 106. In an embodiment, the acoustic emission sensor 106 may be integrated within the portable system 104. In this embodiment, the acoustic emission sensor 106 may be configured to perform on-demand monitoring of the PD in the electrical equipment 102. In some embodiments, the acoustic emission sensor 106 may be integrated within the electrical equipment 102. In this embodiment, the acoustic emission sensor 106 may be configured to perform real-time monitoring of the PD in the electrical equipment 102. The acoustic emission sensor 106 is configured to detect a mechanical wave produced by an electrical discharge event. In other words, the acoustic emission sensor 106 is configured to detect the mechanical wave (or sound waves) generated when the electrical discharge event occurs within the electrical equipment 102.

Upon detecting the mechanical wave produced by the electrical discharge event, the acoustic emission sensor 106 is configured to convert the mechanical wave into an audio signal. In an embodiment, the electrical discharge event refers to a sudden release of electrical energy through a medium, such as air or the insulating material, often in the form of sparks. Examples of the acoustic emission sensor 106 may include, for example, a Physical Acoustic Corporation (PAC) sensor, a Rasor acoustic emission sensor, a Kistler acoustic emission sensor, and the like. In particular, the acoustic emission sensor 106 is an ultrasound detector for detecting the mechanical wave produced by the electrical discharge event that travels through an insulation (also referred to as the insulating material) of the electrical equipment 102 to the surrounding vicinity of the electrical equipment 102. In particular, during the electrical discharge event, the mechanical wave is generated within a solid material of the electrical equipment 102 and travels through different materials until the mechanical wave reaches the acoustic emission sensor 106 made of piezoelectric ceramic. The solid material, for example, may be metals, such as copper, aluminum, etc., and composites, such as glass fiber-reinforced plastics (GFRPs) or carbon fibers.

Once the mechanical wave is converted into the audio signal, a signal processing unit (not shown) may be configured to determine a waveform of the audio signal. In an embodiment, the signal processing unit may be a software block stored within a memory 110 of the portable system 104 and executed in processing circuitry 108. The waveform of the audio signal refers to a shape or a pattern of the audio signal over time. Upon determining the waveform, the signal processing unit is configured to convert the determined waveform into a waveform image. To convert the waveform into the waveform image, the signal processing unit is configured to perform a Short-Time Fourier Transform (STFT) on the audio signal. In general, the STFT is defined as a technique used to analyze non-stationary signals (e.g., the audio signals) by applying a Fourier transform to short, overlapping segments (windows) of a non-stationary signal. The STFT provides a time-frequency representation, showing how the frequency content of the non-stationary signal evolves over time. In an embodiment, the STFT is performed on the audio signal to preserve time information and further convert the audio signal into a spectrogram as the waveform image. The spectrogram is a visual representation of the frequency content of the audio signal over time, created by applying the STFT to the audio signal. The spectrogram displays how the signal's frequencies evolve, with time on the x-axis, frequency on the y-axis, and intensity represented by color or brightness.

In an embodiment, the signal preprocessing unit performs the STFT by breaking the audio signal into small audio segments and taking a Fast Fourier Transform (FFT) of each audio segment. The FFT is an efficient algorithm for computing a Discrete Fourier Transform (DFT) of the audio signal. The FFT transforms a time-domain signal into its frequency-domain representation, revealing the audio signal's frequency components. Further, the signal preprocessing unit constructs the small audio segments into the spectrogram. In an embodiment, the signal preprocessing unit converts the audio signal into the spectrogram by extracting Mel-Frequency Cepstral Coefficients (MFCCs) that represent a short-term power spectrum of sound. In general, the MFCCs of the audio signal are a small set of features that represent an overall shape of the audio signal's spectral envelope, derived from a Mel scale to mimic human hearing. The MFCCs are commonly used to capture timbral and phonetic characteristics, making them useful for speech recognition and audio classification.

The signal preprocessing unit concatenates the MFCCs over time to create a feature vector for each audio segment. The signal processing unit then reshapes the feature vector into the waveform image. In particular, the signal preprocessing unit concatenates features extracted from the STFT and the MFCCs into a matrix. Once the matrix is generated, the matrix is transformed into the waveform image. In an embodiment, the features extracted from the STFT and the MFCCs may be a magnitude spectrum, a phase spectrum, a spectral flux, a logarithmic feature, a delta-delta feature, and the like. Upon generating the waveform image, the waveform image is provided as an input to a Convolution Neural Network (CNN) 112 (also referred to as a CNN model). The CNN 112 takes as input the waveform image to generate an output. The output includes a fault class among four different PD types, which are an arcing (also referred to as an arcing discharge), a corona discharge, a tracking (also referred to as a tracking discharge), a looseness (also referred to as a looseness discharge or a surface discharge), as well as a piece of healthy equipment. In other words, based on the waveform image, the CNN 112 is configured to generate an output indicating the fault class or an output indicating that the electrical equipment 102 is the health equipment. In an embodiment, the CNN may be trained to predict the fault class for the electrical equipment 102 based on a training dataset. The training dataset may include random samples of a plurality of waveform images associated with a plurality of electrical equipment with the four different PD types as well as the health equipment.

Once the fault class is determined, an output device, i.e., an Input/Output (I/O) 114 unit may be configured to output an indication of the fault class of the electrical equipment 102. The indication may be, for example, a visual indication (e.g., a unique color defined for each fault class), an audio indication, etc. In some embodiments, apart from the CNN 112, other neural networks or machine learning models may be used for determining a fault class as long as they can receive as input a waveform image. Examples of other machine learning models can include a Support Vector Machine (SVM), a Random Forest Model, a Long Short-Term Memory (LSTM) Network, a Gradient Boosting Machine (GBM), and the like, and may be used for processing the waveform image to determine the fault class. This complete method of inspecting the electrical equipment 102 for the PD is further explained in detail in conjunction with FIG. 2 to FIG. 24.

The memory 110 may be a volatile memory, such as a Random-Access Memory (RAM), or a non-volatile memory, such as a Read Only Memory (ROM), an Erasable Programmable Read Only Memory (EPROM), a flash memory, and the like. The memory 110 may be configured to store one or more computer-readable instructions or routines that when executed may cause the portable system 104 to inspect the electrical equipment 102 for the PD. The memory 110 may inspect the electrical equipment 102 for the PD in conjunction with a processing circuitry 108. In other words, the processing circuitry 108 may be configured to execute the one or more computer-readable instructions stored within the memory 110 to inspect the electrical equipment 102 for the PD. The processing circuitry 108 may be implemented as one or more microprocessors, microcomputers, microcontrollers, Digital Signal Processors (DSPs), Central Processing Units (CPUs), logic circuitries, and/or any devices that process data based on operational instructions.

In an embodiment, the I/O unit 114 may be used by the user (e.g., the maintenance manager, the safety and compliance officer, etc.) to provide inputs (on/off input) to the portable system 104 to start or stop the portable system 104 operations. Further, the I/O unit 114 may be used to display results, including one or more of the waveform image, the indication of the fault class etc., based on processing performed by the portable system 104 for inspecting the electrical equipment 102 for the PD.

Referring now to FIG. 2, the present disclosure provides an exemplary diagram 200 representing various types of the PD, according to certain embodiments. As depicted in the FIG. 2, the various types of the PD in the electrical equipment includes an internal discharge 202 (i.e., the arcing discharge), a surface discharge 204 (i.e., the looseness discharge), a corona discharge 206, and a tracking discharge 208. The internal discharge 202 occurs within the insulation material where voids, cracks, or gas bubbles exist. In present FIG. 2, voids 202-2 represent places where the internal discharge 202 happens within the insulating material. These voids 202-2 can develop a higher potential than the surrounding insulating material, causing electrical breakdown inside the insulating material. If the internal discharge 202 are not addressed, this internal discharge 202 can progressively damage the insulating material (i.e., the insulation), leading to the tracking or other forms of degradation over time.

The surface discharge 204 happens along a surface 204-2 of the insulating material when there are surface imperfections or loose connections. The surface discharge 204 occurs when an electrical stress is concentrated on the surface 204-2 of the insulating material, causing breakdowns along the surface 204-2. If the surface discharge 204 is left untreated, the surface discharge 204 can escalate into a flashover event, where an electrical current jumps across the surface 204-2, causing catastrophic failure. The catastrophic failure refers to a sudden and complete breakdown of the electrical equipment or a component (e.g., a capacitor, a register, a diode, etc.) of the electrical equipment, often resulting in significant damage or complete loss of functionality.

The corona discharge 206 happens in gaseous environments (such as air or other gases) around high-voltage conductors. The corona discharge 206 occurs when an electric field around a conductor is strong enough to ionize the surrounding gas but not strong enough to cause a full breakdown. A result of the corona discharge 206 is an appearance of a blue cloud 206-2 around the conductor (depicted via circular lines), which indicates ionization of a gas. Though often less damaging than other types of the PD, the corona discharge 206 may lead to an erosion and a degradation of the insulating material if persistent.

The tracking discharge 208 refers to a gradual formation of conductive paths 208-2 along the surface of the insulating material due to prolonged exposure to the PD. As the PD continues in the insulating material, the tracking discharge 208 can create carbonized or eroded areas, allowing the electrical current to travel along the surface of the insulating material. The tracking discharge 208 weakens the insulating material and can eventually lead to a complete failure, such as a flashover, if not repaired.

In particular, the electrical equipment is susceptible to a range of failures, varying from minor to severe, with each type posing different risks and associated costs. For example, wiring looseness is typically considered a minor issue that is relatively inexpensive to fix. On the other hand, more severe failures, such as the tracking discharge 208, can lead to significant repair costs or even replacement of the electrical equipment replacement. These issues have sparked considerable research for understanding the phenomena and effects of the PD on different types of electrical equipment.

For instance, conventionally, the effects of a Direct Current (DC) electric field on DC cables have been studied. The DC electric field causes an accumulation of electrical charges on the surface of the insulating material, increasing a local electric field strength and leading to the PD. As the insulating material degrades, the insulating material becomes more susceptible to the formation of the PD channels, which ultimately results in insulation breakdown. For this, conventionally, a correlation model was developed to study the relationship between ultrasonic waves generated by the electrical equipment and the amount of the PD occurring within the cable. The correlation model helped in analyzing the mechanisms of the PD and the ultrasonic characteristics of the cable.

In an embodiment, High Voltage Direct Current (HVDC) cable systems are also prone to frequent PD. For this, a model has been developed to analyze the correlation between PD ultrasonic waves (also referred to as the mechanical waves) and the number of PD per cable. This conventional model employed a Sagnac fiber detection system, which utilizes the ultrasonic characteristics of various insulating material defects and measures the frequency distribution of the PD. The accuracy of PD localization in this Sagnac fiber detection system was found to be within ±80 meters.

Further, the impact of harmful PD is not limited to DC cables. Insulators carrying DC cables are also vulnerable to failure, which can lead to power interruptions, compromising the reliability of the electrical equipment or an electrical grid. To ensure the reliability of the electrical equipment and meet reliability standards, it is crucial to inspect and monitor the condition of these electrical equipment regularly. Conventionally, a study has been conducted to predict the failure of the distribution of insulating material. The study applied 13.8 kV to a contaminated insulating material and used an ultrasound detector connected to a computer to collect data. This data was then analyzed using a hybrid deep learning technique called a Wavelet Long Short-Term Memory (LSTM) for time series prediction. While this study offered a novel approach using the Wavelet LSTM for analyzing contaminated insulating material, it faced challenges related to safety, data variability, model complexity, and real-world applicability.

Further, the transformers, being integral components of power systems that connect different voltage levels in a power grid (i.e., the electrical grid), are also prone to faults. Malfunctions in the transformers, often caused by electrical or thermal stresses, can result in significant costs, including downtime and repairs. Therefore, early detection of any potential issues in the transformer is essential to prevent unsafe conditions and reduce maintenance costs. In oil-filled transformers, the insulating material (also referred to as insulation) consists of cellulose and oil, and the breakdown of this insulation leads to the formation of gases that dissolve in the oil. Through a Dissolved Gas Analysis (DGA), it is possible to diagnose transformer faults by analyzing the gas composition. However, conventional PD measurement techniques, such as a pulse current method, a high-frequency current method, and the DGA are limited in their ability to locate the exact source of the PD within the transformer. To address this, advanced techniques, such as a hybrid Differential Evolution (DE) algorithm and a Particle Swarm Optimization (PSO), have been developed that demonstrated relatively higher accuracy in the detection and localization of the PD sources. However, these techniques come with their own set of challenges such as a high computational cost and a need for careful hyperparameter tuning, which can limit their real-time application and generalization across varying transformer conditions.

Further, the GIS is another electrical equipment that is a crucial part of the electrical grid and is also vulnerable to the PD issues. Conventionally, to detect the PD issues in the GIS, a Deep CNN (DCNN) model was developed for accurate PD recognition within the GIS. The DCNN model showed superior precision in recognizing PD patterns, outperforming traditional Machine Learning (ML) algorithms, particularly when dealing with high levels of noise. By training the DCNN model on large datasets, the accuracy of recognizing the PD patterns was improved, even in the presence of high noise levels. However, the DCNN model requires large datasets and significant processing power for training and inference.

Currently, an automated recognition of PD faults in the electrical equipment is an increasingly important area, especially in industries where the electrical equipment failure can result in significant production losses and pose safety risks. For example, neglecting active PD in power cables can lead to arc flash (i.e., the arcing discharge), which is not only dangerous but can also result in fatalities or fires. Timely identification of the PD faults is crucial to prevent catastrophic electrical equipment failure and ensure the safety of personnel. Many methods, including Machine Learning (ML) and Deep Learning (DL), have been proposed conventionally for automated recognition of the PD fault recognition, as summarized in Table 1. The Table 1 depicts an accuracy of various Artificial Intelligence (AI) models used conventionally for the PD detection based on ultrasonic data.

In the Table 1, each row of a first column, i.e., ‘electrical equipment’ represents a name of an electrical equipment that was inspected for the PD. Each row of a second column, i.e., ‘AI model’ represents a name of an AI model used for detecting the fault class based on the PD detected within a corresponding electrical equipment. Further, each row of a third column, i.e., ‘accuracy’ represents an accuracy of the fault class predicted by the AI model for the corresponding electrical equipment. For example, for an outdoor insulator, the Artificial Neural Network (ANN)-Backpropagation (BP) model was used to determine the fault class based on the PD detected within the outdoor insulator. Further, the accuracy of the ANN-BP based on the detected fault class is determined to 85%.

TABLE 1

| Electrical Equipment | Artificial Intelligence (AI) | Accuracy |
|---|---|---|
| Outdoor Insulator | Artificial Neural Network | 85% |
| | (ANN) - Backpropagation | |
| | (BP) | |
| Oil-filled submarine cable | ANN-BP | 96% |
| terminal | | |
| Power Transformer | K-Nearest Neighbors (KNN)/ | 98% |
| | Support Vector Machine | |
| | (SVM) | |
| High voltage Bushing | KNN/ANN/SVM/others | 95% |
| Power Transformer | Principal Component Analysis | 94% |
| | (PCA)/KNN | |
| Power Transformer | Gradient Boosting (GB)/ | >90% |
| | Random Forest (RF)/SVM | |
| | and others | |
| Power Transformer | Intelligent Fault Analysis | high |
| | (IFA) | |
| Cross-Linked Polyethylene | CNN | 96% |
| (XLPE) Cable | | |
| Transformer Insulation | CNN | 88% |
| Power Transformer | CNN/Deep Neural Network | 89-93% |
| | (DNN)/Recurrent Neural | |
| | Network (RNN) | |
| PD stimulator | CNN | 74-86% |
| Oil Paper Insulation | KNN/Multilayer Perceptron | 92-99% |
| | (MLP) and others | |
| Insulation for Transformer | ANN | 95% |

Further, to overcome these challenges of the conventional techniques, the present disclosure provides a CNN model (e.g., the CNN model 112) that provides higher accuracy in detection of the PD in the electrical equipment even in the present of high level of field noise. The CNN model may be one of a single-phase CNN model, an optimized single-phase CNN model, or a double-phase CNN model. Each of these CNN models has been described in detailed in conjunction with FIG. 15-FIG. 23.

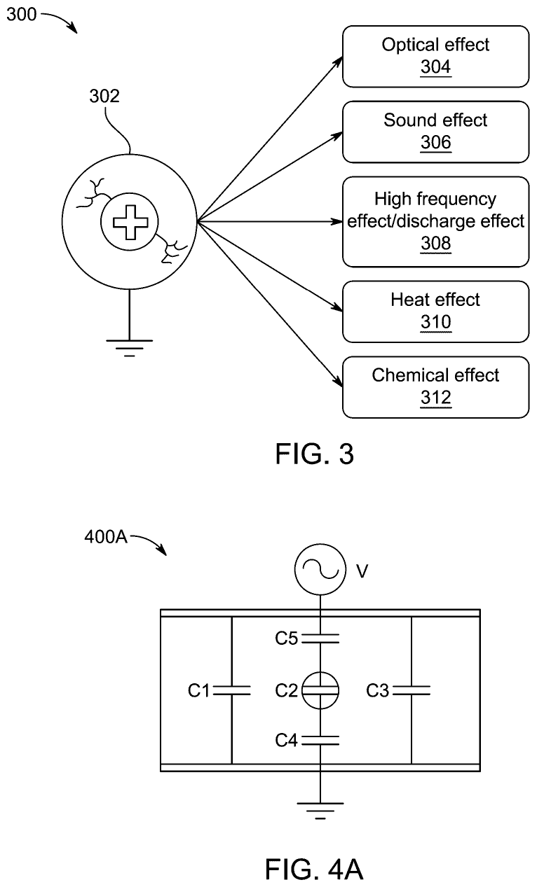

Referring now to FIG. 3, the present disclosure provides an exemplary diagram 300 representing various types of PD detection methods, according to certain embodiments. As depicted via the FIG. 3, the types of PD detection methods for detecting a PD 302 may include an optical effect 304, a sound effect 306, a High Frequency (HF) effect, an Ultra High Frequency (UHF) effect, or a discharge effect 308, a heat effect 310, and a chemical effect 312. The PD 302 may be, for example, the tracking discharge 208. The optical effect 304 is a type of PD detection method that involves observing light emissions (e.g., a light effect) produced by electrical discharge events (also referred to as PD events), such as visible flashes or Ultraviolet (UV) radiations.

In the optical effect 304, specialized cameras or optical sensors are used to detect the light emissions, which help in the identification of PD sources in the electrical equipment (e.g., the electrical equipment 102), especially in high-voltage electrical equipment, such as the transformers or the circuit breakers. The sound effect 306 uses an acoustic emission sensor (same as the acoustic emission sensor 106), i.e., the ultrasound detector to measure sound waves (i.e., the mechanical wave) generated by the electrical discharge events. The electrical discharge events produce high-frequency mechanical waves, often inaudible to human ears, which may be captured using sensitive microphones or the acoustic emission sensor. These mechanical waves help locate and analyze the PD within the electrical equipment.

The HF effect, the UHF effect, or the discharge effect 308 is a type of PD detection method that involves measuring electromagnetic waves (or electromagnetic radiations) emitted during the PD events. The PD typically generates high-frequency electromagnetic waves, which can propagate through the air or along the cables. These high-frequency electromagnetic waves are captured by antennas or UHF sensors that help in detecting the PD in real-time, even in difficult-to-access locations within the electrical equipment. For example, to measure the electromagnetic waves emitted during the PD events, the HF effect, the UHF effect, or the discharge effect 308 detection method uses an international standard, e.g., an International Electrotechnical Commission (IEC) 60270 provides guidelines that involve measuring a charge or current pulses that are emitted during a PD event for the measurement of the PD in the electrical equipment.

Further, the heat effect 310 is a type of PD detection method that monitors the heat generated during the PD events. In particular, the PD within the electrical equipment can cause localized heating due to electrical breakdowns within the insulating material. To detect the PD events using the heat effect 310, Infrared (IR) cameras or thermal sensors are used to detect temperature variations (also referred to as thermography) within the electrical equipment. These temperature variations help in identifying potential fault areas that could lead to a failure of the electrical equipment if left unchecked.

The chemical effect 312 is a type of detection method that involves monitoring chemical byproducts released during the PD events. The PD can cause the breakdown of the insulation material, producing gases like ozone or nitrogen oxides. To detect these gases, the chemical effect 312 uses gas sensors or chemical detectors (e.g., Dissolved Gas Analysis (DGA)). The DGA is a type of chemical detection used to monitor the presence of these gases dissolved in an insulating oil of the electrical equipment. The presence of these gases detected using the gas sensors or the chemical detectors indicates the presence and severity of the PD event in the electrical equipment. These are some of the commonly used unconventional PD detection methods to detect high-frequency PD signals (e.g., the sound waves, the electromagnetic waves) and are immune to electromagnetic interference. However, the present disclosure focuses on the usage of the acoustic emission sensor to detect the mechanical wave (i.e., the sound wave) produced during the electrical discharge events (also referred to as the PD events) and the usage of the CNN (same as the CNN 112) to generate the fault class for the PD detected within the electrical equipment.

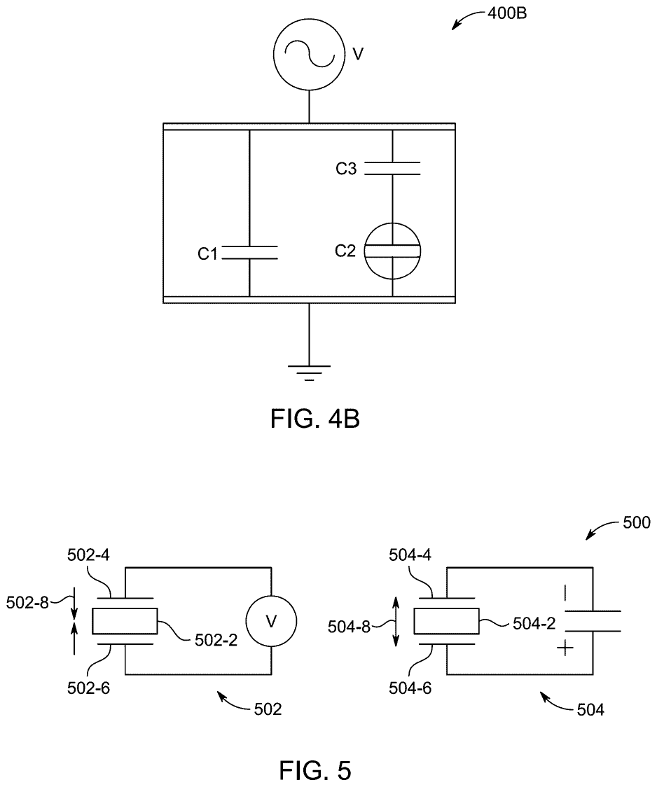

Referring now to FIG. 4A and FIG. 4B, the present disclosure provides an exemplary diagram representing PD models, according to certain embodiments.

In an embodiment, electrical methods used for detecting the PD are not always effective due to electromagnetic interference, which can be difficult to control in a practical field application. Discrimination based on time and frequency domain characteristics is often necessary, and specialized PD couplers may need to be designed to suit a machine used for detecting the PD in the electrical equipment. An acoustic PD detection, i.e., the PD detection using the acoustic emission sensor 106, is preferable in many situations because the acoustic PD detection is immune to electromagnetic interference and does not require significant modification for different electrical equipment being tested for the PD. The acoustic PD detection may be performed while the electrical equipment is operating, providing valuable continuous monitoring of a PD event. The acoustic PD detection may be able to locate a source of the PD event within complex electrical equipment, which is difficult to achieve with the electrical methods.

The acoustic PD detection involves detecting the mechanical waves generated by the PD events. These mechanical waves propagate through the insulating material to the surrounding environment, where they cause local changes in pressure and density. As the mechanical waves travel through the insulating material, these disturbances (i.e., the local changes) cause molecules to move, creating wave motion. For example, when the insulating material is a liquid, the disturbance leads to compression and rarefaction (a reduction in density) of the insulating material. In an embodiment, the behavior of these mechanical waves can be described by a general differential equation, i.e., an equation 1 of an acoustic wave motion.

$${∇}^{2} p = \frac{1}{{c}^{2}} \frac{{\partial }^{2} p}{\partial {t}^{2}} \qquad ( 1 )$$

In the above equation 1, ‘p’ represents the pressure at a point in the insulating material, ‘t’ is a time of the pressure, ‘c’ is a speed of the mechanical wave or a velocity of the mechanical wave in the insulating material (also referred to as a medium), which is determined by properties (e.g., an elasticity or a density) of the insulating material. Further, ‘∇²p’ is a Laplace operator which represents a sum of second partial derivatives of the pressure ‘p’ with respect to spatial coordinates (‘x’, ‘y’, ‘z’). The Laplace operator describes how the pressure ‘p’ varies in space and is used to model wave propagation, such as the mechanical waves generated by the PD events. In three dimensional spaces (‘x’, ‘y’, ‘z’), the sum of the second partial derivatives of the pressure ‘p’ with respect to the space is represented via an equation 2 below:

$${∇}^{2} p = \frac{{\partial }^{2} p}{\partial {x}^{2}} + \frac{{\partial }^{2} p}{\partial {y}^{2}} + \frac{{\partial }^{2} p}{\partial {z}^{2}} \qquad ( 2 )$$

In FIG. 4A, a widely recognized simplified PD model 400A, i.e., Whitehead's three-capacitance circuit model for representing PD phenomena within the insulating materials is depicted. The Whitehead's three-capacitance circuit model is designed to simulate the behavior of the voids (also referred to as gaps) in the insulating material. In order to represent the voids within the insulation material, a circuit model (for example, a Whitehead's three-capacitance circuit model) with 3 capacitances is used. In the Whitehead's three-capacitance circuit model, a capacitor ‘C1’, and a capacitor ‘C3’ represent the capacitance of a healthy insulating material and runs in parallel with capacitors ‘C4’, and ‘C5’. Further, the capacitors ‘C4’, and ‘C5’ reflect a region of the insulating material that are in direct contact with the void, which is represented by a capacitor ‘C2’. In particular, the capacitor ‘C2’ represents the capacitance associated with the void within the insulation material.

The Whitehead's three-capacitance circuit model shown in FIG. 4A can be simplified by using an equivalent simplified three-capacitance circuit model 400B, as shown in FIG. 4B. In the simplified three-capacitance circuit 400B model, capacitors ‘C1’, and ‘C3’ representing the capacitance of the healthy insulating material that are connected in parallel with the series combination of capacitor ‘C2’, ‘C4’, and ‘C5’ as depicted via the FIG. 4A, are replaced with the capacitor ‘C1’ as shown in the simplified three-capacitance circuit 400B model. On the other hand, the capacitors ‘C4’ and ‘C5’ that represents the capacitance of the insulating material and are connected in series with the void (represented via the capacitor ‘C2’) in the FIG. 4A, is replaced with a capacitor ‘C3’ in the simplified three-capacitance circuit model 400B. This simplified three-capacitance circuit model 400B provides an effective electrical representation of the insulating material with the void, allowing for easier analysis and understanding of the PD phenomena in the presence of defects in the insulating material.

In an embodiment, before the PD event, the voltage division across components (i.e., the capacitors) of a capacitive circuit (e.g., the simplified three-capacitance circuit model 400B) is represented via an equation 3 below:

$${v}_{v} = \frac{{X}_{c 3}}{{X}_{C 2} + Xc 3} v \qquad ( 3 )$$

In the above equation 3, ‘vᵥ’ represents the voltage across the void (represented by the capacitor ‘C2’) within the insulating material. ‘v’ is a total applied voltage across the series combination of the capacitors (i.e., the capacitor ‘C2’ (representing the void) and the capacitor ‘C3’ representing the healthy insulating material)) in the simplified three-capacitance circuit 400B. Further, ‘X_{C2}’, ‘Xc3’ represent an impedance of the capacitors, i.e., the capacitor ‘C2’ and the capacitor ‘C3’, respectively.

In an embodiment, when the PD starts developing within the electrical equipment, an electric field force exerted on the void from outside suddenly disappears, causing the void to lose its equilibrium. As a result, the void starts to vibrate due to an elastic force acting on it. This phenomenon of the void losing its equilibrium can be expressed using an equation 4 below:

$${L}_{m} {C}_{m} \frac{{d}^{2} {u}_{c}}{{dt}_{2}} + {R}_{m} {C}_{m} \frac{{du}_{c}}{dt} + {u}_{c} = 0 \qquad ( 4 )$$

In the above equation 4, ‘Lₘ’ is an inductance of an equivalent mechanical circuit, representing an inertial property of the void's movement. ‘Cₘ’ represents the capacitance of the equivalent mechanical circuit. ‘Rₘ’ represents friction losses or resistive forces that oppose the motion of the void. ‘u_{c}’ represents a displacement of the void or an external force acting on the void, determining how far the void moves from its equilibrium position due to changes in the electrical or mechanical forces.

Referring now to FIG. 5, the present disclosure provides an exemplary diagram 500 representing a basic behavior of piezoelectric ceramics, according to certain embodiments. The piezoelectric ceramics (also referred to as a piezoelectric crystal, a piezoelectric transducer, or a piezoelectric element) are materials (e.g., lead zirconate titanate (PZT), barium titanate, quartz, etc.) that generate an electric charge when subjected to mechanical stress (such as pressure, vibration, or deformation). These piezoelectric ceramics exhibit a piezoelectric effect, which is an ability of certain materials to convert mechanical vibrations (i.e., mechanical wave) into electrical signals (i.e., the audio signals) and vice versa. The piezoelectric ceramics are integrated within an acoustic emission sensor (same as the acoustic emission sensor 106) to convert the mechanical waves into the audio signals.

In FIG. 5, a circuit 502 shows a piezoelectric ceramic 502-2 with electrodes (also referred to as metal plates) 502-4 and 502-6 at both ends. The circuit 502 shows a direct piezoelectric effect applied on the piezoelectric ceramic 502-2. In direct piezoelectric effect, when the mechanical stress (such as compression, tension, or vibration) is applied to the piezoelectric ceramic 502-2 as represented by arrows 502-8, it induces a strain in the material (e.g., the PZT) of the piezoelectric ceramic 502-2. This strain leads to a separation of the mechanical vibrations within the piezoelectric ceramic 502-2, generating the electrical signal. Further, the electrical charge generated by the piezoelectric ceramic 502-2 is detected through the electrodes 502-4 and 502-6, which are attached at both ends of the piezoelectric ceramic 502-2 and is measured as a voltage (represented as V). The direct piezoelectric effect is used for sensing mechanical changes (like pressure, vibration, or force) in the electrical equipment.

Further, a circuit 504 shows a piezoelectric ceramic 504-2 with electrodes 504-4 and 504-6 at both ends. The circuit 504 shows a converse piezoelectric effect applied on the piezoelectric ceramic 504-2. In the converse piezoelectric effect, when a voltage (represented as ‘+ and −’ sign) is applied to the piezoelectric ceramic 504-2 through the electrodes 504-4 and 542-, an electrical field is created within the material of the piezoelectric ceramic 504-2. Further, as a result of the electrical field, the piezoelectric ceramic 502-2 either expands or contracts in response to the applied voltage. For example, in current embodiment, the material of the piezoelectric ceramic 504-2 may expand the piezoelectric ceramic 504-2. The converse piezoelectric effect is used for actuation by converting the electrical signals into the mechanical vibrations.

This conversion of the mechanical vibrations into the electrical signals and vice versa by a piezoelectric element (e.g., the piezoelectric ceramic 502-2 and the piezoelectric ceramic 504-2) is referred to as a piezoelectric effect, i.e., the direct piezoelectric effect or the converse piezoelectric effect. The materials that exhibit this piezoelectric effect property are called piezoelectric materials. The piezoelectric ceramics are one such type of the piezoelectric material. Other examples of the piezoelectric material may include a Polyvinylidene Fluoride (PVDF), a tourmaline, a Rochelle salt, and the like.

In an embodiment, the ultrasonic waves (i.e., the mechanical waves) generated by the PD events in the electrical equipment are influenced by two primary factors. A first factor is an occurrence of an electric field force during the PD process. In particular, when the PD event takes place, a localized electrical breakdown of the insulating material creates a rapid ionization of the medium (such as air or gas) in the void. The rapid ionization leads to a sudden release of energy, causing the mechanical vibrations (i.e., the mechanical waves) in the surrounding insulating material, which in turn generate the ultrasonic waves. A second factor influencing the ultrasonic waves is the pressure wave generated by the expansion of the void, or the gas bubble formed as a result of the heat generated by the PD arc. During the PD event, the PD heats up the surrounding insulating material of the electrical equipment, causing a rapid expansion of any gas bubbles or voids present in the insulating material. This rapid expansion of the gas bubbles or the voids creates a pressure wave that propagates through the surrounding insulating material, contributing to the generation of the ultrasonic waves. Both the electric field force and the pressure wave play a crucial role in the formation of the ultrasonic waves, which can be detected and analyzed to assess the severity and location of the PD within the electrical equipment. These ultrasonic waves are valuable indicators of degradation of the insulating material and potential failure, helping to diagnose and prevent further damage to the electrical equipment.

There are two main types of ultrasonic wave detection methodologies used for the PD monitoring, i.e., a structure-borne ultrasonic detection method and an airborne ultrasonic detection method. The structure-borne ultrasonic detection method detects the propagated ultrasonic waves within or along the surface of the insulating material by attaching a sensor (e.g., the acoustic emission sensor) directly to the electrical equipment. This structure-borne ultrasonic detection method is highly accurate and particularly useful in applications where direct exposure to the PD is difficult, such as in live switchgear that cannot be taken offline for inspection. The structure-borne ultrasonic detection method allows for precise detection of the PD even in challenging environments where the PD source is not easily accessible. Further, the airborne ultrasonic detection method, on the other hand, is used when the PD source is either accessible or far from the sensor. This airborne ultrasonic detection method detects the mechanical waves traveling through the air and is effective in environments where the sensor cannot be directly attached to the electrical equipment.

Both the structure-borne ultrasonic detection method and the airborne ultrasonic detection method work by converting the detected mechanical waves into the electrical signals (i.e., the audio signals), using the piezoelectric ceramics or other similar piezoelectric materials. The piezoelectric materials exhibit a reversible relationship between the mechanical stress and the electrical signal. When exposed to the mechanical waves, the acoustic emission sensors including the piezoelectric ceramics generates the electrical signals, i.e., the audio signals proportional to an amplitude and a frequency of the detected mechanical waves. These electrical signals are then processed using conventional data acquisition systems for further analysis and PD localization. In other words, both the structure-borne ultrasonic detection method and the airborne ultrasonic detection method, rely on acoustic emission sensors integrating the piezoelectric ceramics. The piezoelectric ceramics play a vital role in detecting and analyzing the PD events, enabling condition monitoring and fault detection in the electrical equipment.

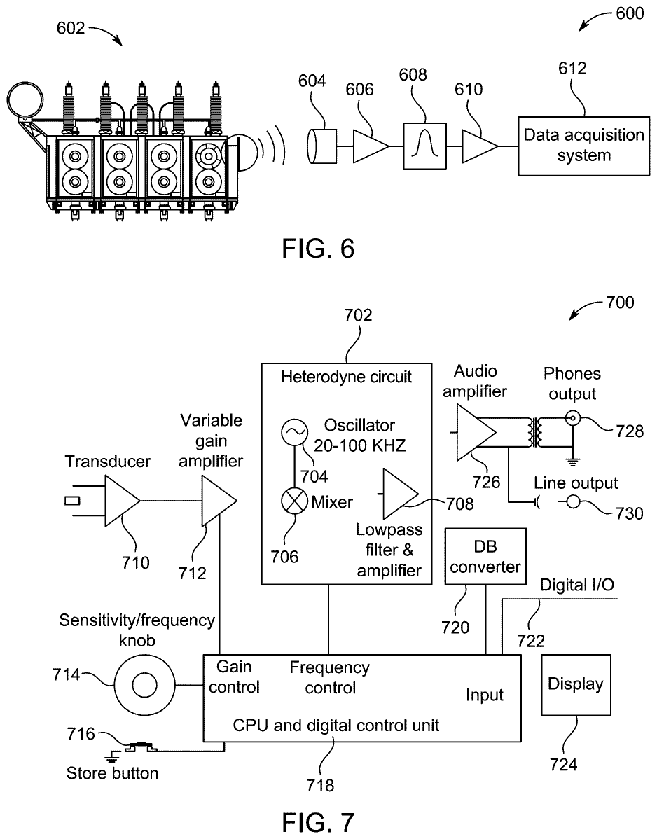

Referring now to FIG. 6, the present disclosure provides an exemplary diagram 600 representing a working principle of the portable system 104, according to certain embodiments. As depicted in FIG. 6, suppose, at step 602, the electrical discharge event (also referred to as an acoustic event or the PD event) occurs with an electrical equipment (e.g., a transformer). When the electrical discharge event occurs in the electrical equipment, the mechanical wave (also referred to as the mechanical vibrations) is generated within the insulating material of the electrical equipment. At step 604, the generated mechanical wave propagates through different insulating materials of the electrical equipment, including structural components (e.g., bushings, circuit breaker enclosure, and the like), until it reaches the acoustic emission sensor. In an embodiment, the acoustic emission sensor is made from the piezoelectric ceramics. When the mechanical wave strikes the piezoelectric ceramic, the mechanical wave induces a deformation within the insulating material. This deformation generates an electrical signal, i.e., the audio signal. At step 606, the generated audio signal is transmitted to a pre-amplifier. The pre-amplifier amplifies the audio signal by minimizing the impact of any noise that might have been introduced into the audio signal from surrounding electrical or mechanical components of the electrical equipment, thereby improving the quality of the audio signal for further analysis.

Once the audio signal is amplified, at step 608, the amplified audio signal passes through a filter. The filter is configured to remove external signals (typically referred to as unwanted signals or noisy signals) from the audio signal, ensuring that only the audio signal relevant to the PD event is passed on for further analysis. For example, a band-pass filter allows frequencies within a specific range (related to the PD event) to pass through, while blocking lower and higher frequencies that might be caused by environmental noise or other electrical interference. Further, once the external signals are removed from the audio signal, at step 610, the audio signal passes through an amplifier. The amplifier increases the strength of the filtered audio signal to detect features of the PD event. Further, at step 612, the audio signal (along with the detected feature) is transferred to a data acquisition system. The data acquisition system may correspond to the signal processing unit present within the memory 110.

The process described in the FIG. 6 enables effective monitoring and analysis of the PD events within the electrical equipment in real time, providing valuable information for predictive maintenance and fault detection in the electrical equipment. In addition, the process allows for an early detection of PD, as the process can detect PD in its early stages.

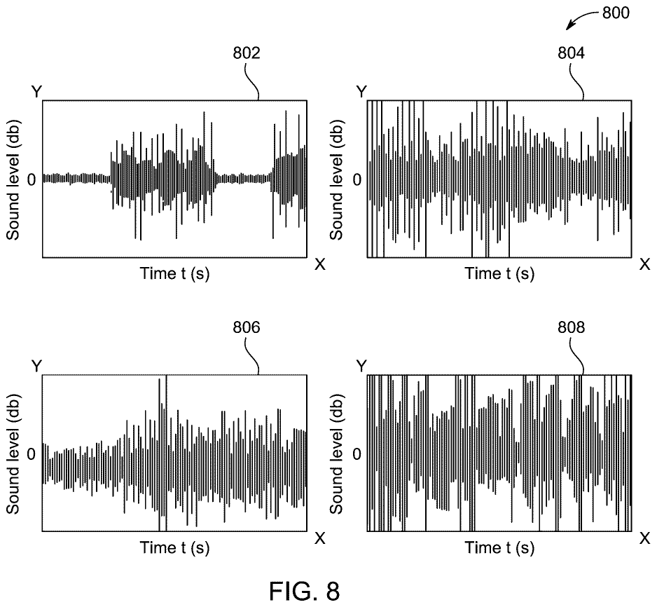

Referring now to FIG. 7, the present disclosure provides an exemplary diagram 700 representing a more recent PD detector circuit, according to certain embodiments. These PD detectors are based on a concept called a superheterodyne detection. The superheterodyne detection is a method used in radio receivers where an incoming signal, e.g., the mechanical wave is mixed with a locally generated frequency (i.e., the frequency generated by a local oscillator) to produce an intermediate frequency (IF) that is easier to process. In FIG. 7, a circuit configuration of a typical superheterodyne-based detector is shown as a heterodyne circuit 702. The heterodyne circuit 702 includes an oscillator 704, a mixer 706, and a lowpass filter and amplifier.

Initially, the mechanical wave is first captured by a transducer 710 (e.g., the acoustic emission sensor), which converts the mechanical wave into the audio signal. Further, the audio signal is amplified using an amplifier 712 (e.g., a variable gain amplifier). Further, the amplified audio signal is sent to the mixer 706. The mixer 706 combines the audio signal with a local oscillator frequency using the oscillator 704. For example, the frequency of the oscillator 704 may be within a range of 20 KiloHertz (KHz)-100 KHz.

The combining of the audio signal with the local oscillator frequency generates two new frequencies, one is the sum of the frequency of an initial audio signal and the local oscillator frequency, and the other is the difference between the frequency of the initial audio signal and the local oscillator frequency. A frequency obtained based on the sum is a higher frequency and is filtered out, while a frequency obtained based on the difference is a lower frequency which is retained, as the lower frequency falls within the range of the frequency of the oscillator 704.

The audio signal with the lower frequency, which corresponds to the difference between the initial audio signal and the local oscillator frequency, is then passed through a filter (e.g., a low pass filter of the low pass filter and amplifier 708) to remove any remaining external signals (also referred to as the unwanted signals or the noisy signals). Finally, the filtered audio signal is further amplified using the amplifier of the low pass filter and amplifier 708 at a final stage before being converted into the audio signal (i.e., audio sound) that is used for the detection and the analysis of the PD events.

Further, as depicted in FIG. 7, a sensitivity/frequency knob 714 and a store button 716 may be connected to a CPU and digital control unit 718. With reference to FIG. 1, the CPU may correspond to the processing circuitry 108, and the digital control unit may correspond to I/O unit 114. The sensitivity/frequency knob 714 allows the user to adjust the gain of the amplifier 712 by rotating the sensitivity/frequency knob 714 to set the gain by which the audio signal needs to be amplified. In addition, the sensitivity/frequency knob 714 allows the user to adjust the frequency of the oscillator 704 by rotating the sensitivity/frequency knob 714. Further, the sensitivity/frequency knob 714 is used by the user to adjust an input provided to a Decibel (dB) convertor 720 required to convert the amplitude of the audio signal into the dB. The store button 716 is used by the user to save the current data or readings (e.g., the mechanical wave, the audio signal, the fault class) generated based on the processing performed by the portable system 104, so that the user may be able to review or use the saved data as per their requirements.

Further, a digital I/O 722 is used to enable communication between the portable system 104 and external devices by handling digital signals. The digital I/O is used to enable the portable system 104 to receive digital input (like on/off signals) from sensors or other external devices and send digital output (like control signals) to actuators, displays, e.g., a display 724, or other devices. The display 724 shows real-time data or results generated by the portable system 104, such as an audio signal strength or the fault class information, to the user.

Further, as depicted in the FIG. 7, the portable system 104 may also include an audio amplifier 726, phones output 728, and a line output 730. The audio amplifier 726 boosts the audio signal for clearer sound output. The phones output 728 allows the user to listen to the audio signals using audio devices, e.g., speakers, headphones, etc. The line output 730 sends the amplified audio signal to external devices (e.g., digital audio recorders, external speakers, etc.) for further processing or recording.

Referring now to FIG. 8, the present disclosure illustrates an exemplary diagram 800 representing time-series waveforms of random audio signal waveform samples, according to certain embodiments.

In an embodiment, waveforms of the audio signal can exhibit a wide range of variations but are generally categorized into distinct patterns based on their visual characteristics. While all the audio signals are associated with the PD, each type of failure (or fault) of the electrical equipment caused by the PD can produce slightly different waveforms. Additionally, some forms of the PD may only appear in a specific electrical equipment, for example, the tracking (also referred to as the tracking discharge) may not be observed in the internal windings of the transformers.

The waveforms of the collected audio signal (e.g., random audio signal waveform samples) have been classified into five distinct categories, one representing a healthy state of the electrical equipment (i.e., the healthy equipment), and four different PD types of the failure or the fault class, i.e., the arcing (also referred to as the arcing discharge), the looseness (also referred to as the surface discharge), the corona discharge, and the tracking. The waveform of the four different PD types of the fault class, i.e., the arcing, the looseness, the corona discharge, and the tracking are illustrated in FIG. 8 via a graph 802, a graph 804, a graph 806, and a graph 808, respectively. To identify the specific type of the fault class, the time-domain waveform is commonly analyzed. However, in some cases, examining the frequency-domain waveform can provide additional insights. For instance, for the corona discharge, which can sometimes resemble the tracking 808 in the time-domain waveform, can be distinguished in the frequency-domain waveform due to the characteristic of higher-frequency components that appear as electrical equipment frequency multiples.

In an experimental aspect, the random audio signal waveform samples are collected from a diverse range of electrical equipment, including power transformers, GISs, control gears, motors, cables, etc. These random audio signal waveform samples are manually classified based on recognizable patterns commonly observed during inspections. To obtain the frequency response of each audio signal waveform sample, a DFT is applied to a time-domain signal as depicted an equation 6 below. Further, a negative spectrum is removed by taking an absolute value of the time-domain signal, ensuring that only the positive frequency components are retained for further analysis.

$$Y [ k ] = {\sum }_{j = 1}^{n} X [ j ] {W}_{n}^{( j - 1 ) ( k - 1 )} \qquad ( 5 )$$

In the above equation 5, ‘Y[k]’ represents a kth frequency component of the DFT. ‘X[j]’ represents j^{th} time-domain sample of the audio signal. ‘Wₙ’ is equal to primitive n^{th} root of a unity, i.e.,

$$‘ {W}_{n} = {e}^{- i} \frac{2 π}{n} ’ .$$

Further, ‘k’ is an index of the frequency bin, ‘j’ is a time-domain index, and ‘n’ is a total number of waveform samples in of the audio signal.

In FIG. 8, in each graph, i.e., the graph 802, the graph 804, the graph 806, and the graph 808, an X-axis represents a time (t) of the audio signal in seconds(s). Further, a Y-axis represents a sound level of the audio signal over time. In particular, the graph 802 represents the variation in the intensity of the sound or the audio signal emitted during the arcing discharge over time. The graph 804 represents the variation in the intensity of the sound or the audio signal emitted during the looseness discharge over time. The graph 806 represents the variation in the intensity of the sound or the audio signal emitted during the corona discharge over time. The graph 808 represents the variation in the intensity of the sound or the audio signal emitted during the tracking discharge over time.

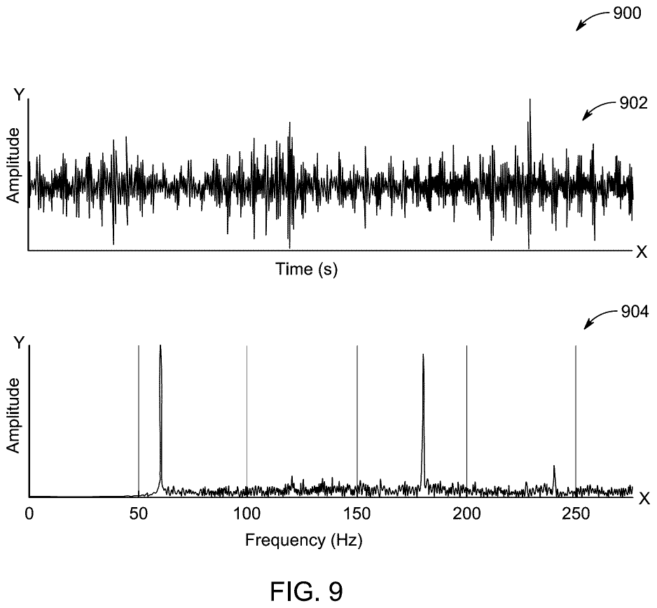

Referring now to FIG. 9, the present disclosure illustrates an exemplary diagram 900 representing a common waveform pattern of the arcing, according to certain embodiments. In FIG. 9, an arcing waveform, i.e., the common waveform pattern of the arcing is represented via an amplitude-time graph 902. An X-axis represents a time(s) depicting the progression of the time, showing how the waveform during the arching discharge evolves over time. Further, a Y-axis represents an amplitude showing the magnitude of the voltage, the current, or the mechanical wave generated by the arcing discharge. Higher peaks on the Y-axis indicate stronger bursts of energy. In particular, the amplitude-time graph 902 provides a time-based visualization of how the intensity of the PD during the arcing changes over time.

Further, another arching waveform is represented via an amplitude-frequency graph 904. An X-axis represents a frequency (in hertz (hz)) indicating how the energy of the audio signal is distributed across various frequencies during the arching discharge. Further, the Y-axis represents an amplitude that show the magnitude or strength of each frequency component of the audio signal generated by the arcing discharge. Higher peaks on the Y-axis indicate that particular frequencies are more dominant or have greater energy in the arcing waveform.

In an embodiment, the arcing waveform is typically characterized by intermittent bursts of the mechanical waves, which occur as a result of a loose wire or a cable gradually building up the voltage until breakdown. Once the breakdown occurs, the arcing waveform generates a high-frequency sound wave, i.e., the audio signal, as illustrated in FIG. 9. In an embodiment, in the frequency-domain waveform, distinct components are usually observed at the electrical equipment frequency and approximately three times the electrical equipment frequency. However, this frequency pattern may not be present in all arcing waveforms.

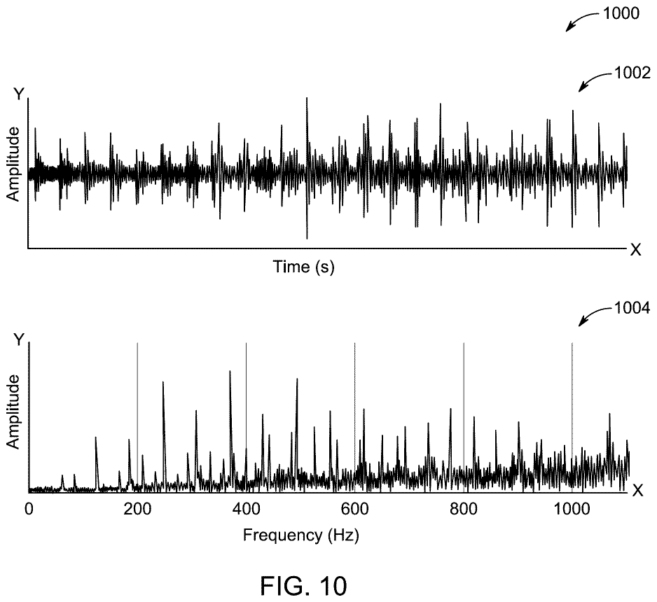

Referring now to FIG. 10, the present disclosure illustrates an exemplary diagram 1000 representing a common waveform pattern of the looseness, according to certain embodiments. In FIG. 10, a looseness waveform, i.e., the common waveform pattern of the looseness is represented via an amplitude-time graph 1002. An X-axis represents a time(s) depicting the progression of the time, showing how the waveform during the looseness discharge evolves over time. Further, a Y-axis represents an amplitude indicating the magnitude of the mechanical wave generated by the looseness discharge, with higher peaks on the Y-axis indicating stronger bursts of energy. In particular, the amplitude-time graph 1002 provides time-based fluctuations in the intensity of the PD caused by mechanical looseness, such as a loose connection or a loose component of the electrical equipment.

Further, another looseness waveform is represented via an amplitude-frequency graph 1004. An X-axis represents a frequency (hz) indicating how the energy of the audio signal is distributed across various frequencies during the looseness discharge. Further, a Y-axis represents an amplitude showing the magnitude or strength of each frequency component of the audio signal generated by the looseness discharge. Higher peaks on the Y-axis indicate that particular frequencies are more dominant or have greater energy in the looseness waveform.

In an embodiment, during an electrical equipment looseness event, the time-domain waveform typically exhibits small triangular bursts of the mechanical waves. In the frequency-domain waveform, the looseness waveform usually contains higher-frequency components compared to the arcing waveform. However, these frequency components are not necessarily multiples of the electrical equipment frequency, as shown in FIG. 10.

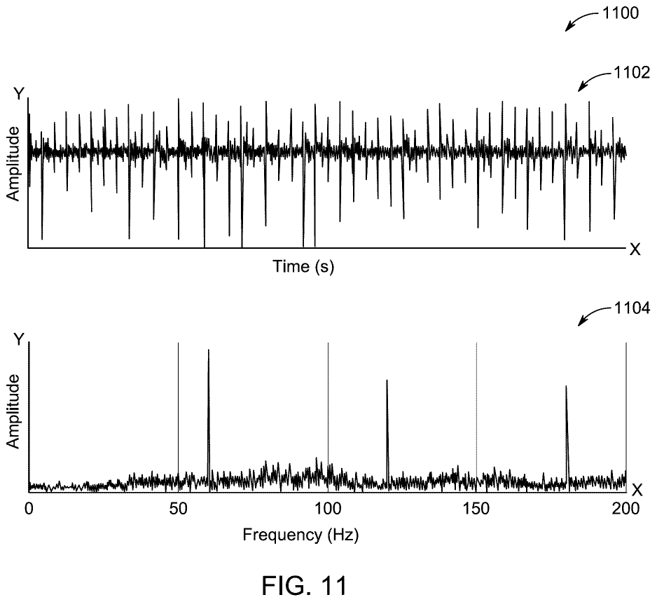

Referring now to FIG. 11, the present disclosure illustrates an exemplary diagram 1100 representing a common waveform pattern of a corona discharge, according to certain embodiments.

In FIG. 11, a corona waveform, i.e., the common waveform pattern of the corona discharge, is represented via an amplitude-time graph 1102. An X-axis represents a time(s) depicting the progression of the time, showing how the waveform during the corona discharge evolves over time. Further, a Y-axis represents an amplitude indicating the magnitude of the mechanical wave generated by the corona discharge, with higher peaks on the Y-axis indicating stronger bursts of energy. In particular, the amplitude-time graph 1002 of the corona waveform represents the variation in the intensity of the PD occurring during a corona event over time.

Further, another corona waveform is represented via an amplitude-frequency graph 1104. An X-axis represents a frequency (hz) indicating how the energy of the audio signal is distributed across various frequencies during the corona discharge. Further, the Y-axis represents an amplitude indicating the magnitude or strength of each frequency component of the audio signal generated by the corona discharge. Higher peaks on the Y-axis indicate that particular frequencies are more dominant or have greater energy in the corona waveform.

In an embodiment, in the case of the corona discharge, the time-domain waveform produces peaks at the electrical equipment frequency, which can be clearly observed in the frequency-domain waveform. The corona discharge generates frequency components at both the electrical equipment frequency and its multiples, as illustrated in FIG. 11.

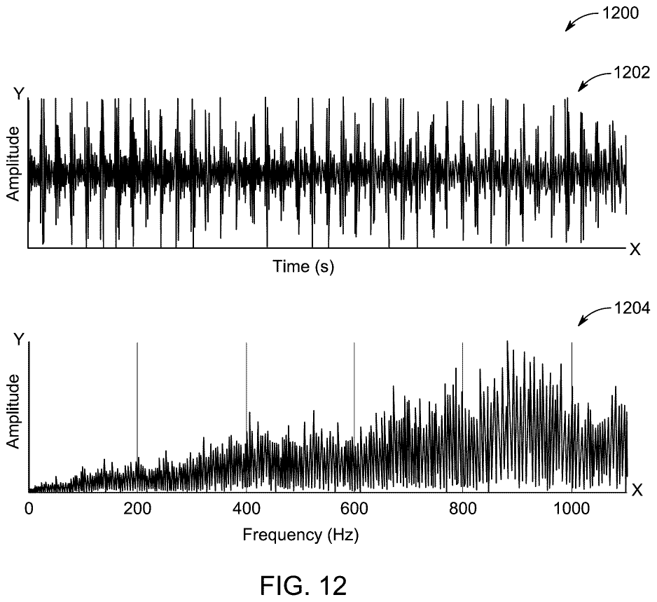

Referring now to FIG. 12, the present disclosure illustrates an exemplary diagram 1200 representing a common waveform pattern of the tracking, according to certain embodiments.

In FIG. 12, a tracking waveform, i.e., the common waveform pattern of the tracking discharge, is represented via an amplitude-time graph 1202. An X-axis represents a time(s) depicting the progression of the time, showing how the waveform during the tracking discharge evolves over time. Further, a Y-axis represents an amplitude indicating the magnitude of the mechanical wave generated by the tracking discharge, with higher peaks on the Y-axis indicating stronger bursts of energy. In particular, the amplitude-time graph 1002 of the tracking waveform represents the variation in the intensity of the PD occurring during a tracking event over time.

Further, another tracking waveform is represented via an amplitude-frequency graph 1204. An X-axis represents a frequency (hz), indicating how the energy of the audio signal is distributed across various frequencies during the tracking discharge. Further, a Y-axis represents an amplitude indicating the magnitude or strength of each frequency component of the audio signal generated by the tracking discharge. Higher peaks on the Y-axis indicate that particular frequencies are more dominant or have greater energy in the tracking waveform. In particular, the tracking waveform is very random and produce high sound intensity with random frequency components as shown in FIG. 12.

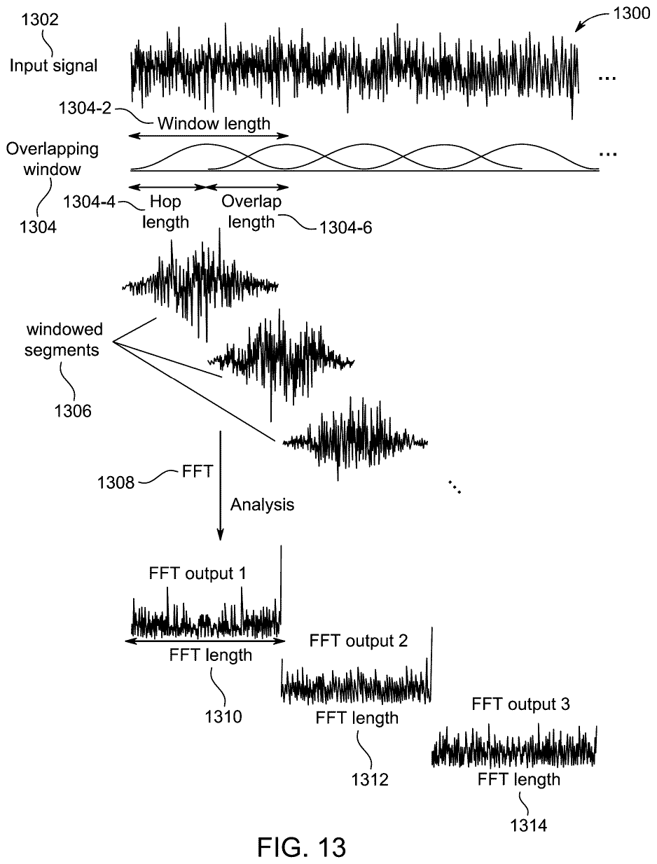

Referring now to FIG. 13, the present disclosure provides an exemplary diagram 1300 representing an implementation of a Short-Time Fourier Transform (STFT) on the audio signals, according to certain embodiments. In an embodiment, after processing the audio signal, the audio signal needs to be prepared for an input into the CNN model (i.e., the CNN 112), which requires the input to be in the form of an image. In other words, the audio signal is converted into the waveform image that is provided as the input to the CNN model for classifying the fault class of the PD within the electrical equipment. To generate the waveform image, key features (e.g., time-domain features, frequency domain features, etc.) are extracted from the audio signal and converted into visual representations. To extract the key features, the STFT is applied to the audio signal. The STFT works by dividing the audio signal into the small audio segments (also referred to as small overlapping segments). Once the audio signal is divided into the small audio segments, the FFT is applied to each audio segment to extract the key features.

As illustrated in FIG. 12, initially, at step 1302, the audio signal (i.e., an input signal) is received. In an embodiment, the audio signal may be received by the signal preprocessing unit of the portable system 104. Upon receiving the audio signal, at step 1304, an overlapping window is identified within the audio signal. The overlapping window is used to segment the audio signal into the small audio segments for analysis. The overlapping window includes an estimation of a window length 1304-2, a hop length 1304-4, and an overlap length 1304-6. In an embodiment, the window length 1304-2 defines a size of each audio segment. The hop length 1304-4 specifies a distance between the start of consecutive windows. The overlap length 1304-6 indicates how much each window overlaps with the previous window.

Further, based on the performing the STFT on the audio signal, at step 1306, the small audio segments may be generated for the audio signal. Once the small audio segments are generated, at step 1308, each audio segment is analyzed using the FFT. In other words, the FFT is taken for each audio segment. In an embodiment, the FFT is applied to each audio segment to convert each audio segment from the time-domain to the frequency-domain. This conversion allows for the extraction of the frequency components (i.e., the frequency domain features) within each audio segment, providing a time-frequency representation of the audio signal. Further, based on the FFT applied to each audio segment, an FFT output may be generated for each audio segment. In embodiment, the FFT output for a small audio segment represents the frequency components of the audio signal, showing how the amplitude of different frequencies varies over time. The FFT provides a spectrum that indicates the audio signal's frequency at a specific moment within each audio segment. As depicted in the FIG. 13, an FFT output 1, an FFT output 2, and an FFT output 3 represent the frequency components of a corresponding small audio element. Further, a FFT length 1310, a FFT length 1312, and a FFT length 1314 represents a length of the frequency component of the corresponding small audio element. Further, once the STFT is completed, the spectrogram is constructed for the small audio segments, which transforms the small audio signals into a two-dimensional (2D) image representation, i.e., the waveform image. The waveform serves as the input for the CNN, enabling the CNN to process the input to generate the fault class for the PD.

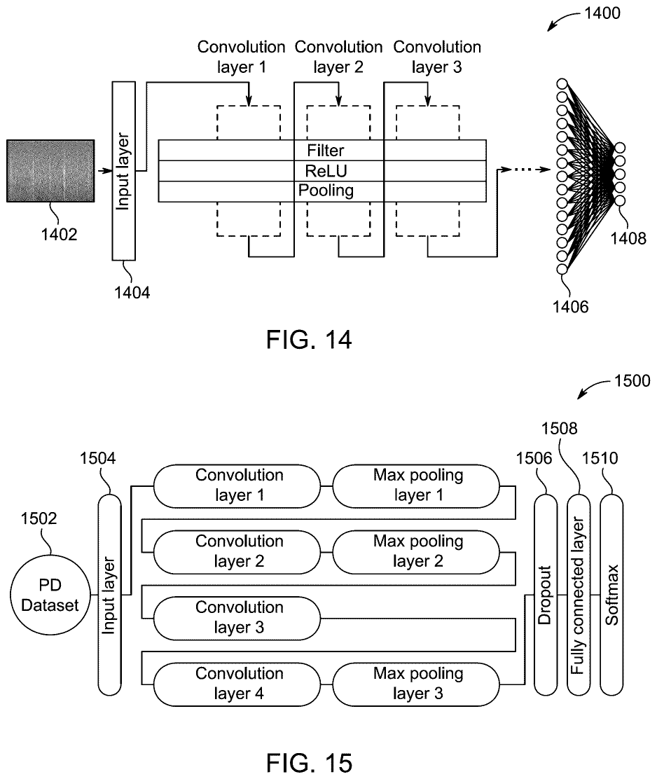

Referring now to FIG. 14, the present disclosure provides an exemplary diagram 1400 representing a general architecture of the CNN (same as the CNN 112), according to certain embodiments. The CNN (also referred to as the CNN model) is a type of deep learning model inspired by a visual processing system found in living organisms. The CNN model consists of multiple layers and are widely used in fields of computer vision and Natural Language Processing (NLP). One of a key strength of CNN model is the ability of the CNN model to automatically learn and extract relevant features from raw input data, such as images or text that makes the CNN model a popular choice for classification in various fields. In particular, the CNN model uses convolutional layers that apply filters to the input data, enabling the CNN model to detect important features, such as edges, textures, and shapes in the images, or semantic relationships in the text provided as the input. The features extracted by the convolutional layers are then passed through fully connected layers, which are responsible for classifying the input or making predictions based on the learned information. The CNN model has proven highly effective in a range of tasks, including image classification, object detection, and the NLP, as the CNN model has the capability to learn hierarchical representations directly from the input data.

In FIG. 14, a waveform image 1402 is depicted. The waveform image 1402 is provided as the input to the CNN model. The CNN model includes multiple layers. The layers for example, may include an input layer 1404, a convolution layer 1, a convolution layer 2, a convolution layer 3, one or more fully connected layers 1406, and an output layer 1408. In an embodiment, only 3 convolution layers are shown for ease of explanation. However, the CNN model may include any number of convolution layers based on the complexity of a task for which the CNN model is being trained for. The input layer 1404 in the CNN model is configured to receive the waveform image 1402, and pass it to subsequent layers (e.g., the convolution layer 1, the convolution layer 2, and so on) for processing. The input layer 1404 defines the dimensions of the input, i.e., the waveform image 1402, including a height, a width, and a depth (number of channels, e.g., Red Green Blue (RGB) for color input images).

The input layer 1404 is configured to provide the waveform image 1402 to the convolution layer 1 for processing. The convolution layer 1, after processing the waveform image 1402, provides a processed waveform image to the convolution layer 2, and the convolution layer 2 further provides the processed waveform image to the convolution layer 3. In particular, each convolution layer applies different convolutional filters to the waveform image 1402, extracting local features such as edges, textures, or patterns from the waveform image 1402. In an embodiment, each subsequent convolutional layer detects increasingly complex features from an output of a previous convolution layer.

Mathematically, the convolution (x*ω) a of two functions ‘x’ and ‘ω’ is defined in all dimensions via an equation 6 below:

$$( x + ω ) a = x ( t ) ω ( a - t ) da \qquad ( 6 )$$

In above equation 6, ‘(x+ω)a’ represents an output of the convolution at a point ‘a’. In other words, it represents the result of convolving the function ‘x’ with the function ‘ω’ at the specific location ‘a’. ‘x(t)’ represents an input function or the input signal that is being convolved. ‘ω(a−t)’ represents a filter or kernel function ‘ω(t)’, shifted by an amount ‘a’, applied to the input function ‘x(t)’. ‘da’ represents a differential element of integration. In an embodiment, a convolutional layer is a crucial element in the CNN model that plays a vital role in generating an output feature map by convolving a set of convolutional kernels or filters with the input image, i.e., the waveform image 1402.

As depicted via the FIG. 14, each convolution layer includes a filter, a Rectifier Linear Unit (ReLU), and one or more pooling layers. The filter is a small matrix that slides over the waveform image 1402 or a feature map to detect specific features, such as edges or textures. The filter performs convolution by computing dot products between the filter and local regions of the waveform image 1402.

The ReLU is an activation function applied after a convolution operation. The ReLU introduces non-linearity by replacing all negative values in the feature map with zero, allowing the CNN model to learn complex patterns. In particular, the ReLU is a widely used activation function in the CNN model. The ReLU is designed to convert all negative input values to zero while maintaining positive values. The ReLU activation function is computationally inexpensive compared to other activation functions. Mathematically, the ReLU is represented as depicted via an equation 7 below:

$${f ( x )}_{Re LU} = max ( 0 , x ) \qquad ( 7 )$$

In the above equation 7, ‘ƒ(x)’ represents an output of the activation function (ReLU). ‘x’ is an input value to the ReLU, which could be an output of the convolution operation or the feature map from the previous convolution layer.

In the CNN model, the activation function is key to transforming the input (i.e., the waveform image 1402) into the output (i.e., the fault class). The input to a neuron is computed by taking a weighted sum of the input, with an optional bias term added. The activation function then determines whether the neuron will activate, producing a specific output based on the input. Essentially, the activation function introduces non-linearity into the CNN model, enabling the CNN model to determine more complex relationships and make more sophisticated decisions. This process allows the CNN model to learn and adapt to intricate patterns in the input data.

The one or more pooling layers are a vital part of the CNN model, designed to perform sub-sampling on the feature map generated by the convolutional operation. By reducing the spatial dimensions of the feature map, the one or more pooling layers help to extract the most dominant features in each region of the waveform image 1402, while preserving the most important information. This down-sampling process performed by the one or more pooling layers not only makes the CNN model more computationally efficient but also helps improve the ability of the CNN model to generalize by focusing on the most significant features.

Further, the final layers in the CNN model are composed of the fully connected layers 1406. In the fully connected layers 1406, each neuron is connected to every neuron in a previous fully connected layer, creating a dense network. Further, a last fully connected layer functions as an output layer, generating a classification result, i.e., the fault class of the PD within the electrical equipment. These fully connected layers 1406 can be mathematically represented by the following general equations 8 and 9 below:

$${ω}_{ij}^{h} ( t + 1 ) = {ω}_{ij}^{h} ( t ) + η {x}_{j} {φ}^{′} {\sum }_{k}^{L} ( {e}_{k} {ω}_{k} i ) \qquad ( 8 )$$

$${b}_{ij}^{h} ( t + 1 ) = {b}_{ij}^{h} ( t ) + η {φ}^{′} {\sum }_{k}^{L} ( {e}_{k} {ω}_{k} i ) \qquad ( 9 )$$

In the above equations 8 and 9,

$$‘ {ω}_{ij}^{h} ( t + 1 ) ’$$

represents an updated weight between a neuron ‘i’ in a fully connected layer ‘h’ and a neuron ‘j’ in a previous fully connected layer at time step ‘(t+1)’.

$$‘ {ω}_{ij}^{h} ( t ) ’$$

a weight between the neuron ‘i’ in the fully connected layer ‘h’ and the neuron ‘j’ in the previous fully connected layer at time step ‘t’. ‘xⱼ’ an input from the neuron ‘j’ in the previous fully connected layer.

$$‘ {b}_{ij}^{h} ( t + 1 ) ’$$

represents an updated bias term for the neuron ‘i’ in a fully connected layer ‘h’ and the neuron ‘j’ at time step ‘(t+1)’.

$$‘ {b}_{ij}^{h} ( t ) ’$$

a bias term between the neuron ‘t’ in the fully connected layer ‘h’ and the neuron ‘j’ at time step ‘t’. ‘η’ represents a learning rate, which controls how much the weights are adjusted. ‘φ′’ represents a derivative of the activation function of the neuron ‘j’. ‘eₖ’ represents an error term for a neuron ‘k’ in the next fully connected layer. ‘ωₖi’ represents a weight connecting the neuron ‘i’ and the neuron ‘k’. ‘L’ represents a total number of fully connected layers in the CNN model. In an embodiment, the above equation 8 and 9 are used to update weights ‘ωᵢⱼ’ and biases ‘bᵢⱼ’ which is derived from the least mean square method depicted via an equation 10 below:

$$I = \frac{1}{2} {\sum }_{k}^{L} {( {Y}_{k} - {Y}_{k}^{h} )}^{2} \qquad ( 10 )$$

In the above equation 10, ‘I’ represents an error function (i.e., the loss function) that measures the difference between a predicted output and a true output. ‘Yₖ’ represents a true output (i.e., a target value) for the neuron ‘k’ output.

$$‘ {Y}_{k}^{h} ’$$

a predicted output from the CNN model (i.e., the output generated after a final forward pass to the last fully connected layer). ‘L’ represents a total number of output neurons.

In an embodiment, the architecture of the CNN model has many hyperparameters that can be tuned, such as a filter size, a number of convolutional layers, a learning rate, an input image size, the number of neurons in the fully connected layers, and the like. While these hyperparameters can be tuned through trial and error, more efficient and robust methods, like A Bayesian optimization, can significantly improve an accuracy of the CNN model and reduce loss. These efficient and robust optimization techniques systematically search the hyperparameter space, enabling more effective optimization and reducing the need for manual tuning, leading to better performance in a more efficient manner. The Bayesian optimization is an algorithm designed to solve global optimization problems using Bayes' Theorem. The global optimization involves finding input parameters that minimize or maximize a given objective function. These objective functions are often complex and are characterized by non-convexity, nonlinearity, high-dimensionality, noise, and high computational cost, making the objective functions challenging to analyze. The Bayesian optimization provides an efficient solution to these difficulties by systematically exploring the hyperparameter space. The Bayesian optimization effectively identifies an optimal set of hyperparameters, achieving the best possible results with fewer evaluations of the objective function.

Referring now to FIG. 15, the present disclosure provides an exemplary diagram 1500 depicting a CNN architecture for a single-phase method, according to certain embodiments. The CNN model operating on the single-phase method is referred to as the single-phase CNN model. The single-phase method refers to the detection of the fault class upon determining the electrical equipment to a faulty equipment in a single operation of the CNN model. In other words, the single-phase CNN model is configured to determine whether the electrical equipment under test for the PD is healthy equipment or is electrical equipment with one of the four different PD types in a single-phase execution. In an embodiment, the main objective of the CNN model is to classify any detected fault during the operation of the electrical equipment in one of the fault class, so that the user (e.g., the maintenance manager) can take action to rectify the fault. In an embodiment, the rectification of the fault in the electrical equipment may sometimes just involve cleaning the electrical equipment, but other times, the rectification involves shutting down the entire process of which the electrical equipment is the part and taking the electrical equipment out of service for extended periods. To train the CNN model for detecting the fault class, the random waveform image samples of the PD was collected. A Table 2 shows a number of waveform image samples collected from healthy equipment and a number of waveform image samples collected from faulty equipment.

TABLE 2

| Equipment Condition | Collected Samples |
|---|---|
| Faulty Equipment | 1824 |
| Faulty Equipment | 1732 |

In the above Table 2, each row of a first column, i.e., ‘electrical equipment’, represents a type of the electrical equipment, i.e., a healthy equipment or a faulty equipment. Further, each row of a second column, i.e., ‘collected samples’ represents a total number of waveform image samples collected for the PD for each type of the electrical equipment.

A Table 3 represents a number of waveform image samples collected for each type of the PD, i.e., the fault class of the PD, e.g., the arcing discharge, the corona discharge, the looseness discharge, the tracking discharge. In the Table 3, each row of a first column, i.e., ‘PD type’ represents a type of the PD. Further, each row of a second column, i.e., ‘collected samples’, represents a total number of waveform image samples collected for each PD type. For example, for the arcing discharge, the total number of waveform image samples collected may be 356.

TABLE 3

| PD Type | Collected Samples |
|---|---|
| Arcing | 356 |
| Corona | 442 |
| Looseness | 506 |
| Tracking | 520 |

After collecting the random waveform image samples, parameters (such as number of layers, number of each type of layers, learning rate, etc.) are selected for the CNN model to train the CNN model in predicting the fault class. As depicted in FIG. 15, a PD dataset 1502 may be provided as an input to the CNN. The PD dataset 1502 may include the total waveform image samples collected for the healthy equipment and the faulty equipment, along with the type of PD associated with the faulty equipment, as depicted in Table 2 and Table 3. In particular, the PD dataset 1502 may include a waveform image of each collected sample. Further, an input layer 1504 (same as the input layer 1404) may be configured to receive the PD dataset as the input. Further, as depicted in FIG. 15, the architecture of the CNN model includes a set of four convolution layers, i.e., a convolution layer 1, a convolution layer 2, a convolution layer 3, and a convolution layer 4, and a set of three pooling layers represented as a max pooling layer 1, a max pooling layer 2, and a max pooling layer 3. Each convolution layer and each pooling layer may be configured to process each waveform image present in the PD dataset 1502. The functioning of the convolution layer and the pooling have been explained in the description of FIG. 14.

Further, as depicted in the FIG. 15, the architecture of the CNN model includes a dropout layer 1506, one or more fully connected layers 1508, and a softmax layer 1510. The functioning of one or more fully connected layers 1508 has been explained in the description of FIG. 14. The dropout layer 1506 is used in the CNN model (and other deep learning models) to help prevent overfitting. The overfitting occurs when the CNN model demonstrates high performance on a training data, i.e., the PD dataset 1502, but struggles to generalize well to unseen data (e.g., testing data or a real-time data). Further, the softmax layer 1510 in the CNN model is typically used as a final layer for multi-class classification tasks, converting raw output scores (log its) of the CNN model into probabilities. The softmax layer 1510 normalizes the log its into a probability distribution, where each output corresponds to the likelihood of each fault class, summing to 1.

Table 4 below represents a name of each parameter of the CNN model along with a selected value for each parameter. In the Table 4, each row of a first column, i.e., ‘parameter’ represents a name of a parameter associated with the CNN model. Further, each row of a second column, i.e., ‘selected value’ represents a specified value of each parameter. For example, a second row in the Table 4 represents a parameter, i.e., a number of layers, along with its value, i.e., 22. In other words, the CNN selected for training includes 22 layers in total.

TABLE 4

| Parameter | Selected Value |
|---|---|
| Number of layers | 22 |
| Input layer size | 86 × 86 × 3 |
| 1st Convolution Layer size | 86 × 86 × 32 |
| 2nd Convolution Layer size | 43 × 43 × 64 |
| 3rd Convolution Layer size | 21 × 21 × 128 |
| 4th Convolution Layer size | 21 × 21 × 128 |
| 1st pooling Layer size | 43 × 43 × 32 |
| 2nd pooling Layer size | 21 × 21 × 64 |
| 3rd pooling Layer size | 10 × 10 × 128 |
| Fully connected layers/(neurons in | 2/(512)-(5) |
| each layer) | |
| Max Epochs | 20 |
| Mini-Batch size | 32 |
| Training-Validation-Testing | 70%-15%-15% |
| percentages | |
| Validation frequency | 10 |
| Initial learning rate | 0.001 |
| Learning rate drop factor | 0.1 |
| Learning rate drop period | 15 |

In an embodiment, the values of each parameter of the CNN model are selected based on trial and error, in addition to best practices used by experts (e.g., developers). The set of four convolution layers in the CNN model is capable of learning several features that are extracted from the mechanical waves, e.g. time, frequency, timbral and pitch information that are extracted using the FTT and the MFCC.

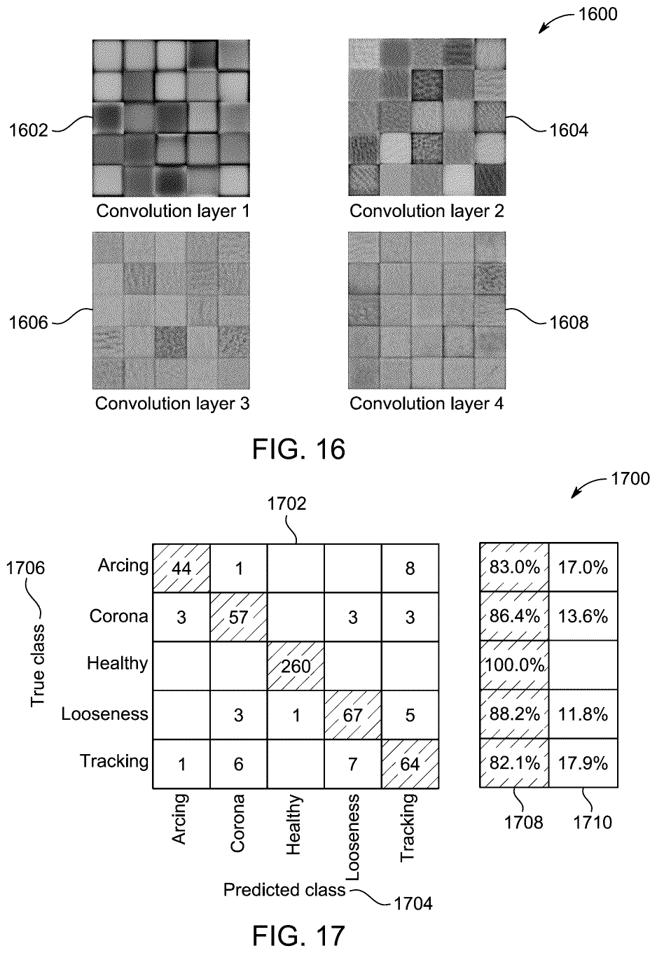

Referring now to FIG. 16, the present disclosure provides an exemplary diagram 1600 representing a pictorial representation of features detection performed by convolution layers of the CNN (same as the CNN 112), according to certain embodiments. FIG. 16 is explained in conjunction with FIG. 15. The convolution layer may correspond to the convolution layer 1, the convolution layer 2, the convolution layer 3, the convolution layer 4 of the FIG. 15. As depicted in FIG. 16, a pictorial representation 1602, a pictorial representation 1604, a pictorial representation 1606, and a pictorial representation 1608 shows the features (such as edges, colors, texture, etc.) of an image (e.g., the waveform image) learned by each convolution layer, i.e., the convolution layer 1, the convolution layer 2, the convolution layer 3, and the convolution layer 4, respectively.

As depicted in FIG. 16, each successive convolutional layer captures more complex patterns, such as edges, corners, and finer textures, of the waveform image, which are essential for understanding more sophisticated visual structures that are detected by combining the features learned by a previous convolution layer. For example, the pictorial representation 1602 shows the learned features of the convolution layer 1. The learned features of the convolution layer 1 primarily capture simple patterns such as colors and basic textures. Further, as the CNN (also referred to as the CNN model) progresses deeper into the convolutional layers, the features become increasingly complex and detailed, evolving to capture higher-level structures like edges, shapes, and intricate textures, with each passing convolution layer as depicted via the pictorial representation 1604, the pictorial representation 1606, and the pictorial representation 1608.

Referring now to FIG. 17, the present disclosure provides an exemplary diagram 1700 representing a confusion matrix 1702 generated for the CNN operating on the single-phase method, according to certain embodiments. FIG. 17 is explained in conjunction with FIG. 15 and FIG. 16. The confusion matrix 1702 is a table used to evaluate the performance of the CNN (also referred to as the CNN model), particularly in the context of multi-class classification (i.e., the fault class classification). In particular, the confusion matrix 1702 represents the performance of the single-phase CNN model. The confusion matrix 1702 compares a predicted class 1704 from the CNN model with a true class 1706 (i.e., a ground truth) of the PD dataset 1502, showing how well the CNN model performs in distinguishing between different PD fault classes, i.e., the arching discharge, the corona discharge, the looseness discharge, the tracking discharge, as well as the health equipment. As represented by the confusion matrix 1702, rows represent the true class 1706, and columns represent the predicted class 1704.

For example, as represented via the confusion matrix 1702, diagonal elements (i.e., M_{1,1}, M_{2,2}, M_{3,3}, M_{4,4}, M_{5,5}) (represented using a dark grey color) of the confusion matrix 1702 may represent true positive instances where the CNN model correctly predicts the type of the fault class, as well as the healthy equipment. For example, if the CNN model correctly classifies an instance of the arcing discharge as the arcing discharge, it's a true positive for the arcing discharge. Further, off-diagonal elements (e.g., M_{1,2}, M_{1,3}, M_{1,4}, M_{1,5}, M_{2,3}, M_{2,4}, M_{2,5}, M_{3,4}, M_{3,1}, M_{3,2}, M_{4,1}, M_{4,2}, M_{4,3}, M_{5,1}, M_{5,2}, etc., represented using a light grey color) of the confusion matrix 1702 may represent misclassification, i.e., false positive instances or false negative instances, where the CNN model mistakenly classifies one fault class as another fault class or incorrectly misses the fault class. For example, if an instance of the arcing discharge is misclassified by the CNN model as the corona discharge, it's a false positive for the corona discharge. For example, if the CNN model fails to identify the arcing discharge and classifies it as the healthy equipment, this would be a false negative for the arcing discharge. Further, each column of a row 1708 may represent an accuracy percentage of the true positive instances for each fault class. Further, each column of a row 1710 may represent an accuracy percentage of the false positive instances or the false negative instances for each fault class.

In an embodiment, as depicted by the confusion matrix 1702, the tracking discharge exhibited the lowest accuracy percentage due to random nature of the mechanical wave detected by the acoustic emission sensor (same as the acoustic emission sensor 106). In contrast, the healthy equipment achieved a highest accuracy percentage, as the mechanical wave produced are unique in waveform and typically do not generate a high-frequency noise.

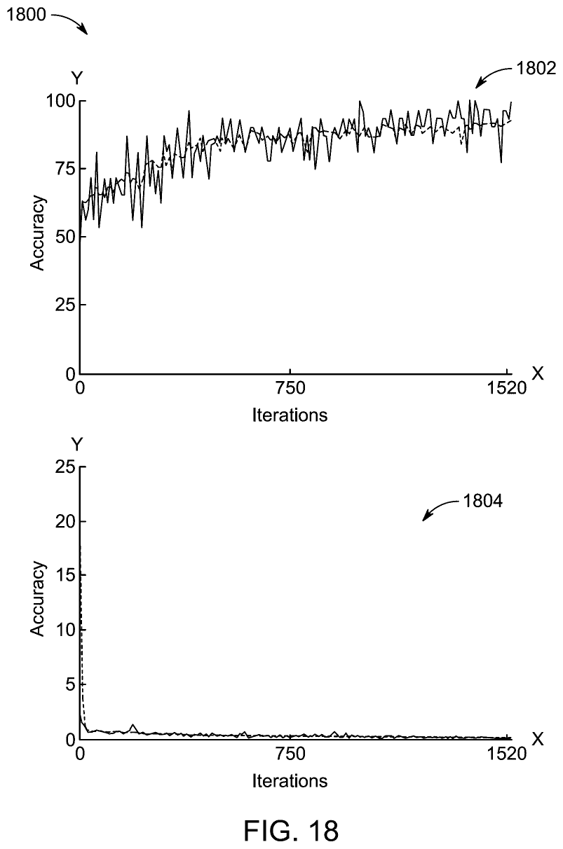

Referring now to FIG. 18, the present disclosure provides an exemplary diagram 1800 representing training versus validation graphs generated for the CNN (same as the CNN 112) operating on the single-phase method, according to certain embodiments. FIG. 18 is explained in conjunction with FIG. 15, FIG. 16, and FIG. 17. In FIG. 18, each of a training versus validation graph 1802 and a training versus validation graph 1804 represent the performance of the CNN model, i.e., how the CNN model evolves over time during each iteration of one complete training cycle. An X-axis represents a number of iterations in a training cycle. Further, a Y-axis represents a validation accuracy or a validation loss of the CNN model during each iteration in the training cycle. The training and validation graphs 1802 and 1804, shown in FIG. 18, demonstrate a significant improvement in both the validation accuracy and the validation loss as the number of iterations increases. A Table 5 represents results of output parameters, e.g., a training accuracy, a validation accuracy, a final accuracy, a simulation time, etc., for the CNN model operating on the single-phase method. Each row of a first column, i.e., ‘output parameters’ represent a name of an output parameter. Each row of a second column, i.e., ‘results’, represents a value of each output parameter. For example, the training accuracy of the single-phase CNN model is determined to be 98%.

TABLE 5

| Output Parameters | Results |
|---|---|
| Training accuracy | 98% |
| Validation accuracy | 92% |
| Training loss | 0.038 |
| Validation loss | 0.023 |
| Number of iterations | 1540 |
| Training time | 159 seconds |

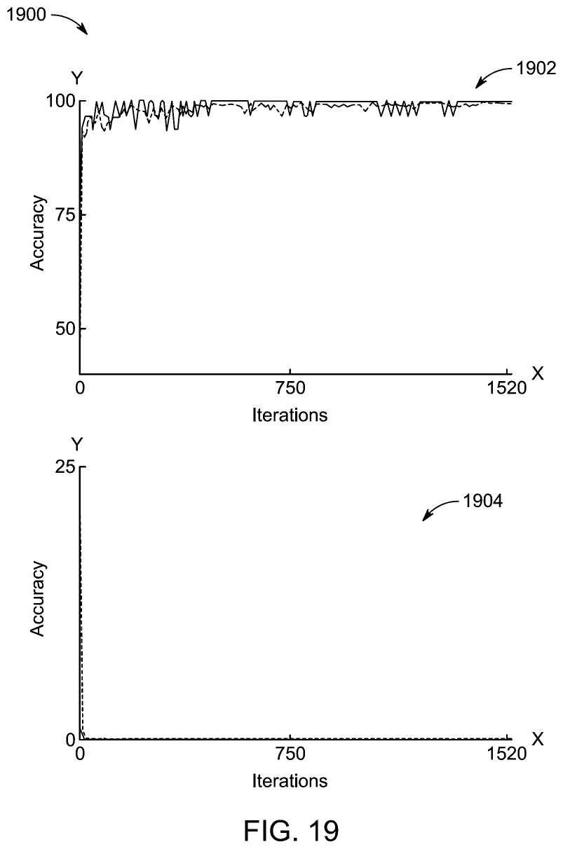

Referring now to FIG. 19, the present disclosure provides an exemplary diagram 1900 representing training versus validation graphs generated for the CNN operating on a double-phase method, according to certain embodiments. The CNN operating on a double-phase method may be also referred to as the double-phase CNN model (e.g., the CNN 112). In some embodiments, during maintenance inspections performed by the user (e.g., the maintenance manager) for the electrical equipment, the maintenance manager may be first interested in only knowing whether the electrical equipment is healthy or not. To address this need of the maintenance manager, the CNN (i.e., the CNN model) can be designed to first classify whether the electrical equipment is the healthy equipment or the faulty equipment as a first phase. If the electrical equipment is classified as the faulty equipment, the CNN model can then identify a specific type of the fault class in a second phase. This two-phase approach, i.e., the double-phase method allows the CNN model to provide a clear and actionable response, significantly enhancing its overall accuracy.

In the double-phase method of the CNN model, the parameters from the CNN model operating on the single-phase method are largely retained, with a primary modification being an output classifier, which is updated to include two classifications, i.e., one for the healthy equipment and another for the faulty equipment. This primary modification leads to improved performance, as shown via a training versus validation graph 1902 and a training versus validation graph 1904 in the FIG. 19. The training versus validation graph 1902 and the training versus validation graph 1904 are generated by the double-phase CNN model. Similar to FIG. 18, an X-axis of the training versus validation graph 1902 and the training versus validation graph 1904 represents a number of iterations in a training cycle. Further, a Y-axis of the training versus validation graph 1902 and the training versus validation graph 1904 represents a validation accuracy or a validation loss of the CNN model during each iteration in the training cycle. As depicted in FIG. 19, the training versus validation graphs 1902 and 1904 generated by the double-phase CNN model demonstrate a robust convergence after just a few iterations, indicating improved performance of the double-phase CNN model and more accurate detection of the fault class for the PD in the electrical equipment.

Table 6 represents results of the output parameters, e.g., the training accuracy, the validation accuracy, the training time, etc., for the double-phase CNN model. Each row of a first column, i.e., ‘output parameters’ represent a name of the output parameter. Each row of a second column, i.e., ‘results’, represents a value of each output parameter. For example, the training accuracy of the double-phase CNN model is determined to be 98%.

TABLE 6

| Output Parameters | Results |
|---|---|
| Training accuracy | 100% |
| Validation accuracy | 99.62% |
| Training loss | 9.6* 10⁻⁵ |
| Validation loss | 0.016 |
| Number of iterations | 1540 |
| Training time | 206 seconds |

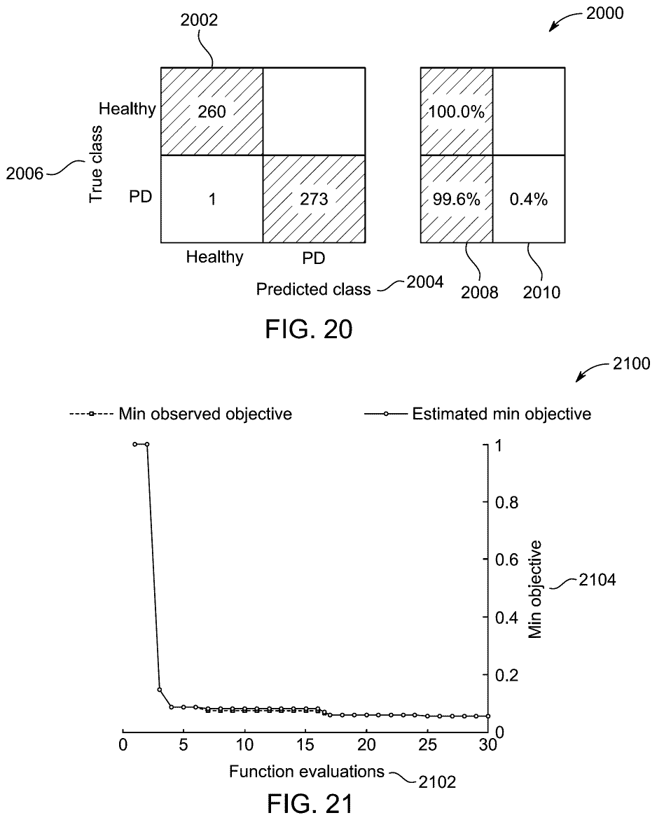

Referring now to FIG. 20, the present disclosure provides an exemplary diagram 2000 representing a confusion matrix 2002 generated for a first phase of the CNN operating on the double-phase method (also referred to as the double-phase CNN model), according to certain embodiments. The confusion matrix 2002 is generated based on classification performed by the double-phase CNN model during the first phase, i.e., the classification of the health equipment (depicted as ‘healthy’) and the faulty equipment (depicted as ‘PD’).

As represented by the confusion matrix 2002, rows represent a true class 2006, and columns represent a predicted class 2004. For example, as represented via the confusion matrix 2002, diagonal elements (i.e., M_{1,1} and M_{2,2}) (represented using a dark grey color) of the confusion matrix 2002 may represent true positive instances where the double-phase CNN model correctly predicts the type of the electrical equipment, i.e., the healthy equipment or the faulty equipment. For example, if the double-phase CNN model correctly classifies an instance of a healthy electrical equipment as the healthy equipment, it's a true positive for the healthy equipment. For example, 260 instances of a healthy electrical equipment were correctly classified as the healthy equipment by the double-phase CNN model which are the true positive instances. Similarly, 273 instances of a faulty electrical equipment were correctly classified as the faulty equipment by the double-phase CNN model which are the true positive instances.

Further, off-diagonal elements (e.g., M_{2,1} and M_{1,2}, represented using a light grey color) of the confusion matrix 2002 may represent misclassification, i.e., the false positive instances or the false negative instances, where the double-phase CNN model mistakenly misclassifies the type of the electrical equipment. For example, as depicted via the confusion matrix 2002, one instance of the healthy electrical equipment was misclassified as the faulty equipment, depicting it as a false positive instance for the healthy electrical equipment classification. Further, each column of a row 2008 may represent an accuracy percentage of the true positive instances for each of the type of electrical equipment classification. Further, each column of a row 2010 may represent an accuracy percentage of the false positive instances or the false negative instances for each of the type of electrical equipment classification. In an embodiment, all faulty electrical equipment (i.e., the electrical equipment with the PD) generates high-frequency components that can be easily distinguished from the silent waveforms of the healthy equipment.

Referring now to FIG. 21, the present disclosure provides an exemplary diagram representing a graph 2100 depicting a progress of an objective function applied to the CNN operating on the single-phase method, according to certain embodiments. In an embodiment, to increase the accuracy of the CNN operating on the single-phase method (i.e., the single-phase CNN model), the Bayesian optimization is applied. The Bayesian optimization is a probabilistic model-based optimization technique used to find a global optimum of a complex, high-dimensional, and noisy objective function. The Bayesian optimization uses Bayes' Theorem to update beliefs about the objective function and efficiently explores the parameter (e.g., edges, colors, etc.) space to identify optimal solutions. In the present disclosure, the goal of the Bayesian optimization is to minimize the validation classification error, which serves as the objective function. To achieve this, several hyperparameters are tuned within a specified range.

For optimizing the single-phase CNN model, four hyperparameters are selected. The four hyperparameters include a section depth, an initial learning rate, momentum, and regularization. The section depth determines the depth of the single-phase CNN model by specifying the number of convolution layers in each section. The initial learning rate is used to control the adaption of the single-phase CNN model weights during training. The momentum helps accelerate a gradient descent process by adding a fraction of a previous weight update to a current weight update. The regularization is a technique used to prevent overfitting by adding a penalty term to the loss function, encouraging a simpler single-phase CNN model. Table 7 below represents the name of each selected hyperparameter along with an associated search range value and a scale. Each column of a first row, i.e., ‘hyperparameter’, represents the name of the hyperparameters. Each column of a second row, i.e., ‘search range’, represents possible minimum and maximum values that the hyperparameter can take. Each column of a third column, i.e., ‘scale’, indicates how values of the hyperparameters are distributed and explored, e.g., in a form of an integer, a log, or a real value.

TABLE 7

| Hyperparameters | Search Range | Scale |
|---|---|---|
| Section depth | [1-4] | Integer |
| Initial learning rate | [1*10⁻³] | Log |
| Momentum | [0.8-0.98] | Real |
| Regularization | [1*10⁻¹⁰-1*10⁻²] | Log |

Once the single-phase CNN model is optimized using the Bayesian optimization based on the four hyperparameters, results achieved using the hyperparameters determined using the Bayesian optimization are presented via a Table 8. The results reflect the performance of the optimized single-phase CNN model once the hyperparameters have been fine-tuned to their best values, leading to improved efficiency and accuracy. In the Table 8, each column of a first row, i.e., hyperparameter, represents the name of the hyperparameter. Each row of a second column, i.e., optimal value, represents an optimal value of each hyperparameter for the optimized single-phase CNN model.

TABLE 8

| Hyperparameters | Optimal Value |
|---|---|
| Section depth | 2 |
| Initial learning rate | 0.0042 |
| Momentum | 0.8035 |
| Regularization | 1.237 |

Further, the graph 2100 depicts the progress of the objective function applied on the single-phase CNN model to generate the optimized single-phase CNN model. In graph 2100, an X-axis, i.e., represents an evaluation of the objective function based on the four hyperparameters through the number of iterations in the one complete training cycle depicted as function evaluations 2102. Further, a Y-axis represents a minimum objective 2104, i.e., a minimum value of the objective function achieved during the training process of the optimized single-phase CNN model. The Y-axis shows how well the optimization is progressing, with lower values of the hyperparameters indicating better performance of the optimized single-phase CNN model. In the graph 2100, a bold black line represents a minimum observed objective, and a thin black line represents an estimated minimum objective. The minimum observed objective is an actual minimum value of the objective function observed during the optimization process of the single-phase CNN model. Further, the estimated minimum objective is a minimum value of the objective function estimated by the user for the optimization process of the single-phase CNN model.

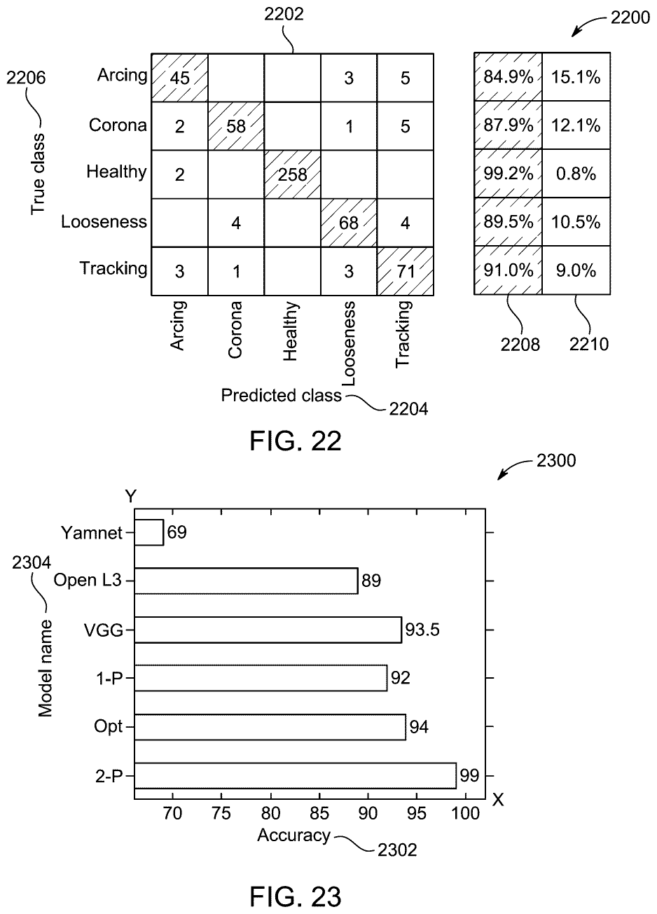

Referring now to FIG. 22, the present disclosure provides an exemplary diagram 2200 representing a confusion matrix 2202 generated by the CNN operating on the single-phase method after applying the objective function (also referred to as the optimized single-phase CNN model), according to certain embodiments. As depicted via the confusion matrix 2202, an overall accuracy, as well as the validation accuracy of the optimized single-phase CNN model of classifying each type of the PD has improved after applying the objective function as compared to the single-phase CNN model before applying the objective function. In the confusion matrix 2202, rows represent a true class 2206, and columns represent a predicted class 2204. For example, as represented via the confusion matrix 2202, diagonal elements (i.e., M_{1,1}, M_{2,2}, M_{3,3}, M_{4,4}, M_{5,5}) (represented using a dark grey color) of the confusion matrix 2202 may represent true positive instances where the optimized single-phase CNN model correctly predicts the type of the fault class. Further, off-diagonal elements (e.g., M_{1,2}, M_{1,3}, M_{1,4}, M_{1,5}, M_{2,3}, M_{2,4}, M_{2,5}, M_{3,4}, M_{3,1}, M_{3,2}, M_{4,1}, M_{4,2}, M_{4,3}, M_{5,1}, M_{5,2}, etc., represented using a light grey color) of the confusion matrix 2202 may represent misclassification, i.e., false positive instances or false negative instances, where the optimized single-phase CNN model misclassifies one fault class as another fault class or incorrectly misses the fault class. Further, each column of a row 2208 may represent an accuracy percentage of the true positive instances for each fault class. Further, each column of a row 2210 may represent an accuracy percentage of the false positive instances or the false negative instances for each fault class. Further, as depicted by the confusion matrix 2202, the accuracy of the optimized single-phase CNN model for detecting the tracking discharge shows the most significant improvement as compared to other remaining fault classes.

Referring now to FIG. 23, the present disclosure provides an exemplary diagram representing a bar graph 2300 depicting experimental results of various existing pre-trained models with disclosed CNN models, according to certain embodiments. In particular, the training dataset (i.e., the PD dataset 1502) defined in the present disclosure is used on the various existing pre-trained models for detecting the PD in the electrical equipment. Examples of the existing pre-trained models include a Visual Geometry Group (VGG) for Audio (VGGish), an Open-source Latent Layer Learning (OpenL3), and a Yet Another Mobile Network (YAMNet). Further, the disclosed CNN models include the double-phase CNN model, the single-phase CNN model, and the optimized single-phase CNN model. In an embodiment, the double-phase CNN model, the single-phase CNN model, and the optimized single-phase CNN model may be the CNN 112.

The VGGish is a CNN model pre-trained by Google. An architecture of the VGGish draws inspiration from the widely used VGG networks, which are known for their effectiveness in image classification tasks. The VGGish consists of a series of convolutional and activation layers, followed by a possible max pooling layer. A full network architecture contains a total of 17 layers. Further, the OpenL3 is a deep audio embedding framework developed as an open-source project. Building upon a self-supervised L3-Network, the OpenL3 introduces several enhancements to an original architecture of the CNN model. The OpenL3 model outperforms the VGGish, a Sound Network (i.e., SoundNet), and even an original L3-Network on a range of sound recognition tasks. The YAMNet is a pretrained model specifically designed for acoustic detection tasks. Developed by Dan Ellis, the YAMNet is trained using an AudioSet dataset, which consists of labeled data from over two million YouTube videos. The YAMNet employs a depth-wise separable convolution architecture derived from MobileNet_version 1, which helps reduce the number of parameters and enables efficient computation, making it well-suited for mobile devices and resource-constrained environments.

In bar graph 2300, an X-axis, i.e., accuracy 2302, represents the accuracy of each model (i.e., the existing pre-trained models and the disclosed CNN models) based on the PD dataset 1502. Further, a Y-axis, i.e., model name 2304, represents a name of each model. As depicted via the bar graph 2300, the YAMNet showed an accuracy of 69%. The OpenL3 showed an accuracy of 89%. The VGGish shows an accuracy of 93.5%. Further, the single-phase CNN model (depicted as 1-P) showed an accuracy of 92%. The optimized single-phase CNN model (depicted as opt) showed an accuracy of 94%. Further, the double-phase CNN model (depicted as 2-P) showed an accuracy of 100%.

In an embodiment, in the present disclosure, the PD dataset 1502 with the four distinct types of the PD (i.e., the arcing discharge, the corona discharge, the looseness discharge, and the tracking discharge) was collected from a variety of electrical equipment in a real-world field environment, where noise presents a significant challenge. Each type of the PD generates a unique audio signal that can be detected using an acoustic sensor. Initially, a general analysis of the audio signals was performed, which are then classified before a preprocessing stage of the audio signal. Following this, a novel methodology was implemented to preprocess the PD dataset 1502, utilizing different feature extraction techniques, i.e., the STFT, the FFT, the MFCC, and a Power Spectral Density (PSD).

Further, three types of CNN models, i.e., the single-phase CNN model (i.e., the CNN operating on the single-phase method), the double-phase CNN model (i.e., the CNN operating on the double-phase method), and the optimized single-phase CNN model (i.e., the CNN operating on the single-phase method after the optimizing process) were trained and validated based the PD dataset 1502. These three CNN models demonstrated superior accuracy compared to state-of-the-art pre-trained models, highlighting their effectiveness in the PD detection and classification.

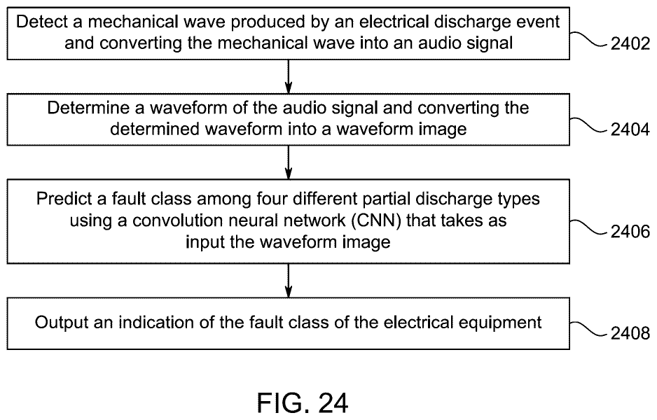

Referring now to FIG. 24, the present disclosure provides an exemplary diagram depicting a flowchart of a method of classifying the PD in the electrical equipment, according to certain embodiments. In order to classify the PD in the electrical equipment, initially, at step 2402, the mechanical wave produced by the electrical discharge event in the electrical equipment is detected using the acoustic emission sensor (i.e., the acoustic emission sensor 106). In an embodiment, the electrical discharge event refers to a sudden release of electrical energy through a medium, such as air or the insulating material, often in the form of sparks. Examples of acoustic emission sensors may include, for example, the PAC sensor, the Rasor acoustic emission sensor, the Kistler acoustic emission sensor, and the like. Further, the PD in the electrical equipment refers to the localized electrical discharge or the sparking that occurs within the insulating material (i.e., the insulation) of the electrical equipment. The PD in the electrical equipment is caused by the presence of the void, the crack, or the gas bubble within the insulating material. The insulating material of the electrical equipment is used to prevent an unwanted flow of electrical current, ensuring safety by protecting against electric shock and short circuits. The insulating material also helps maintain efficient operation by reducing energy losses and electrical interference. Examples of the electrical equipment may include, but are not limited to, the transformer, the GIS, the circuit breaker, the capacitor, and the cable. Further, the insulating material may be, for example, the rubber, the PE, the PVC, the epoxy resin, the glass, the polyimide, and the like.

In an embodiment, the detection of the mechanical wave is performed by the ultrasound detector (i.e., the acoustic emission sensor) that detects the mechanical wave that travels through the insulation (i.e., the insulating material) of the electrical equipment to the surrounding vicinity of the electrical equipment. In particular, the electrical discharge event in the electrical equipment generates the mechanical wave within the solid material of the electrical equipment and the mechanical wave travels through different materials until it reaches the acoustic emission sensor made of piezoelectric ceramic. The solid material, for example, may be metals, such as copper, aluminum, etc., and composites, such as glass fiber-reinforced plastics (GFRPs) or carbon fibers. Upon detecting the mechanical wave, the mechanical wave is converted into the audio signal using the acoustic emission sensor.

Further, at step 2404, the waveform of the audio signal was determined. Upon determining the waveform, the determined waveform is converted into the waveform image. In order to convert the determined waveform into the waveform image, the STFT is performed on the audio signal. In general, the STFT is defined as the technique used to analyze non-stationary signals (e.g., the audio signals) by applying the Fourier transform to short, overlapping segments (windows) of a non-stationary signal. The STFT provides the time-frequency representation, showing how the frequency content of the non-stationary signal evolves over time. In an embodiment, the STFT is performed to preserve time information in the audio signal and to further convert the audio signal into the spectrogram as the waveform image. The spectrogram is the visual representation of the frequency content of the audio signal over time, created by applying the STFT to the audio signal. The spectrogram displays how the signal's frequencies evolve, with time on the x-axis, frequency on the y-axis, and intensity represented by color or brightness. In an embodiment, to perform the STFT, the audio signal is divided into the small audio segments and the FFT is taken for each audio segment. In general, the FFT is an efficient algorithm for computing a Discrete Fourier Transform (DFT) of the audio signal. The FFT transforms a time-domain signal into its frequency-domain representation, revealing the audio signal's frequency components.

Once the audio signal is divided into the small audio segments, the small audio segments are converted into the spectrogram. In an embodiment, the small audio segments are converted into the spectrogram by extracting the MFCCs that represents the short-term power spectrum of sound. In general, the MFCCs of the audio signal are the small set of features that represent the overall shape of the audio signal's spectral envelope, derived from the Mel scale to mimic human hearing. The MFCCs are commonly used to capture timbral and phonetic characteristics, making them useful for speech recognition and audio classification. Further, features extracted from the STFT and the MFCCs are concatenated into the matrix (e.g., a confusion matrix), and the matrix is transformed into the waveform image. Further, the waveform image is provided as the input to the CNN, e.g., the CNN 112 (also referred to as the CNN model). The CNN model may be one of the single-phase CNN model, the double-phase CNN model, or the optimized single-phase CNN model. In an embodiment, the MFCCs are concatenated over time to create the feature vector for each audio segment. Further, the feature vector created is reshaped into the waveform image. In other words, the frequency information is extracted from the audio signal and the time feature is preserved from the audio signal (i.e., PD sound) by implementing the STFT for each audio signal that shows recognizable behavior for each type of the PD. Further, the MFCCs is applied to extract further information (such as timbre or texture of the sound) from the audio signal that cannot be extracted using the STFT. All information (i.e., the features) extracted from the STFT and the MFCCs is concatenated into one matrix and then transformed into an image (i.e., the waveform image). This image is further provided as the input to the CNN model. In particular, the STFT is a good representation of the audio signal but the MFCCs can enhance the representation of any audio signal representing the PD.

In particular, the STFT analyzes the audio signal in short overlapping windows, providing a time-frequency representation. This allows to capture how the frequency content of the audio signal changes over time, which is especially useful for non-stationary audio signals like the PD. However, two audio signals with similar STFT representations, makes it challenging to distinguish between them. The MFCCs are used in such instances. The MFCCs are designed to capture the perceptual characteristics of the sound signal by focusing on a human ear's response to different frequencies. The MFCCs extract a set of coefficients that represent the short-term power spectrum of sound, emphasizing important features for tasks like speech and audio recognition, which can be done artificially.

Further, at step 2406, the waveform image is provided as the input to the CNN (i.e., the CNN model) to generate an output, i.e., the fault class among the four different PD types, as well as the healthy equipment. In particular, the CNN model is trained to determine the fault class among the four different PD types which are the arcing (also referred to as the arcing discharge or the internal discharge), the corona discharge, the tracking (also referred to as the tracking discharge), the looseness (also referred to as the looseness discharge or the surface discharge), as well as the healthy equipment by distinguishing between audio signals. Further, once the output is generated by the CNN, at step 2408, an indication of the fault class of the electrical equipment is provided to the user (e.g., the maintenance manager, the safety and compliance officer, etc.).

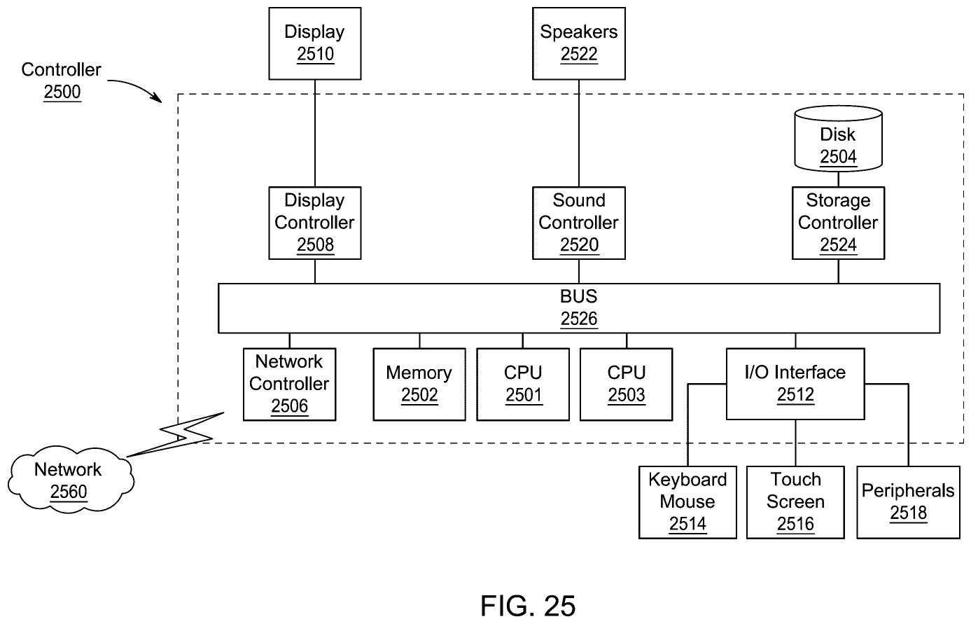

Next, further details of the hardware description of the computing environment according to exemplary embodiments is described with reference to FIG. 25. In FIG. 25, a controller 2500 that is described is representative of the portable system 104 of FIG. 1 in which the controller 2500 is a computing device which includes a CPU 2501 which performs the processes described above/below. The process data and instructions may be stored in a memory 2502. These processes and instructions may also be stored on a storage medium disk 2504 such as a Hard Disk Drive (HDD) or a portable storage medium or may be stored remotely.

Further, the present disclosure is not limited by the form of the computer-readable media on which the instructions of the inventive process are stored. For example, the instructions may be stored on Compact Disks (CDs), Digital Versatile Discs DVDs, in a FLASH memory, a RAM, a ROM, a Programmable Read-Only Memory (PROM), an EPROM, an Electrically Erasable Programmable Read-Only Memory (EEPROM), a hard disk or any other information processing device with which the computing device communicates, such as a server or a computer.

Further, the present disclosure may be provided as a utility application, background daemon, or component of an operating system, or combination thereof, executing in conjunction with the CPU 2501, 2503 and an Operating System (OS) such as a Microsoft Windows 7, a Microsoft Windows 10, a UNIX, a Solaris, a LINUX, an Apple MAC-OS and other systems known to those skilled in the art.

The hardware elements in order to achieve the computing device may be realized by various circuitry elements, known to those skilled in the art. For example, the CPU 2501 or the CPU 2503 may be a Xenon or a Core processor from Intel of America or an Opteron processor from Advanced Micro Devices (AMD) of America, or may be other processor types that would be recognized by one of ordinary skill in the art. Alternatively, the CPU 2501, the CPU 2503 may be implemented on a Field-Programmable Gate Array (FPGA), an Application-Specific Integrated Circuit (ASIC), a Programmable Logic Device (PLD) or using discrete logic circuits, as one of ordinary skill in the art would recognize. Further, the CPU 2501, the CPU 2503 may be implemented as multiple processors cooperatively working in parallel to perform the instructions of the inventive processes described above.

The computing device in FIG. 25 also includes a network controller 2506, such as an Intel Ethernet Professional (PRO) network interface card from an Intel Corporation of America, for interfacing with a network 2560. As can be appreciated, the network 2560 can be a public network, such as the Internet, or a private network such as a LAN or a WAN, or any combination thereof and can also include a PSTN or an Integrated Services Digital Network (ISDN) sub-networks. The network 2560 can also be wired, such as an Ethernet network, or can be wireless such as a cellular network including EDGE, Third Generation (3G), and Fourth Generation (4G) wireless cellular systems. The wireless network can also be a Wi-Fi, a Bluetooth, or any other wireless form of communication that is known.

The computing device further includes a display controller 2508, such as a NVIDIA GeForce Giga Texel Shader eXtreme (GTX) or a Quadro graphics adaptor from a NVIDIA Corporation of America for interfacing with display a 2510, such as a Hewlett Packard (HP) L2445w LCD monitor. A general purpose I/O interface 2512 interfaces with a keyboard and/or a mouse 2514 as well as a touch screen panel 2516 on or separate from the display 2510. The general purpose I/O interface 2512 also connects to a variety of peripherals 2518 including printers and scanners, such as an OfficeJet or a DeskJet from the HP.

A sound controller 2520 is also provided in the computing device, such as a Sound Blaster X-Fi Titanium from Creative, to interface with speakers/microphones 2522 thereby providing sounds and/or music.

A general purpose storage controller 2524 connects the storage medium disk 2504 with a communication bus 2526, which may be an Industry Standard Architecture (ISA), an Extended Industry Standard Architecture (EISA), a Video Electronics Standards Association (VESA), a Peripheral Component Interconnect (PCI), or similar, for interconnecting all of the components of the computing device. A description of the general features and functionality of the display 2510, the keyboard and/or mouse 2514, as well as the display controller 2508, the storage controller 2524, the network controller 2506, the sound controller 2520, and the general purpose I/O interface 2512 is omitted herein for brevity as these features are known.

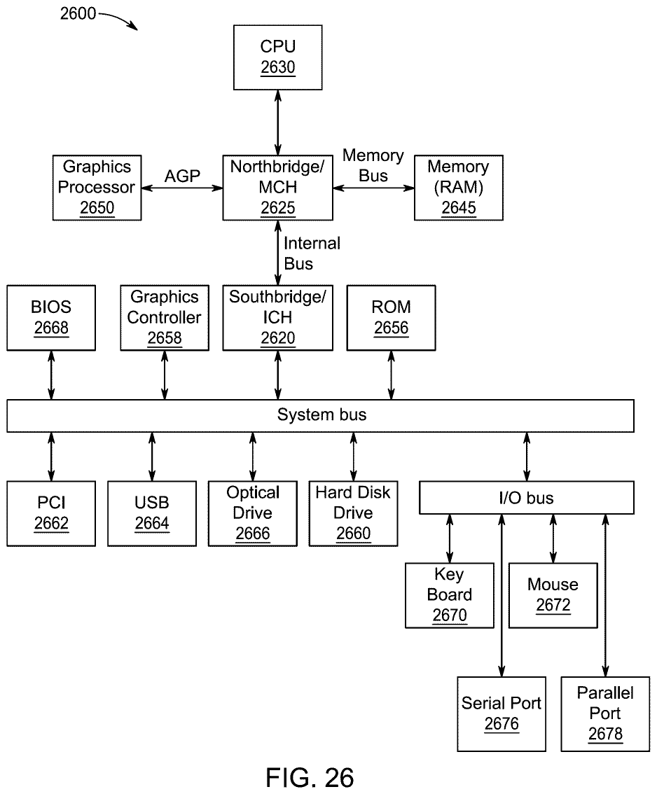

The exemplary circuit elements described in the context of the present disclosure may be replaced with other elements and structured differently than the examples provided herein. Moreover, circuitry configured to perform features described herein may be implemented in multiple circuit units (e.g., chips), or the features may be combined in circuitry on a single chipset, as shown on FIG. 26.

FIG. 26 shows a schematic diagram of a data processing system 2600, according to certain embodiments, for performing the functions of the exemplary embodiments. The data processing system 2600 is an example of a computer in which code or instructions implementing the processes of the illustrative embodiments may be located.

In FIG. 26, the data processing system 2600 employs a hub architecture including a North Bridge and a Memory Controller Hub (NB/MCH) 2625 and a South Bridge and I/O Controller Hub (SB/ICH) 2620. The CPU 2630 is connected to the NB/MCH 2625. The NB/MCH 2625 also connects to the memory 2645 via a memory bus and connects to a graphics processor 2650 via an Accelerated Graphics Port (AGP). The NB/MCH 2625 also connects to the SB/ICH 2620 via an internal bus (e.g., a unified media interface or a direct media interface). The CPU 2630 may contain one or more processors and even may be implemented using one or more heterogeneous processor systems.

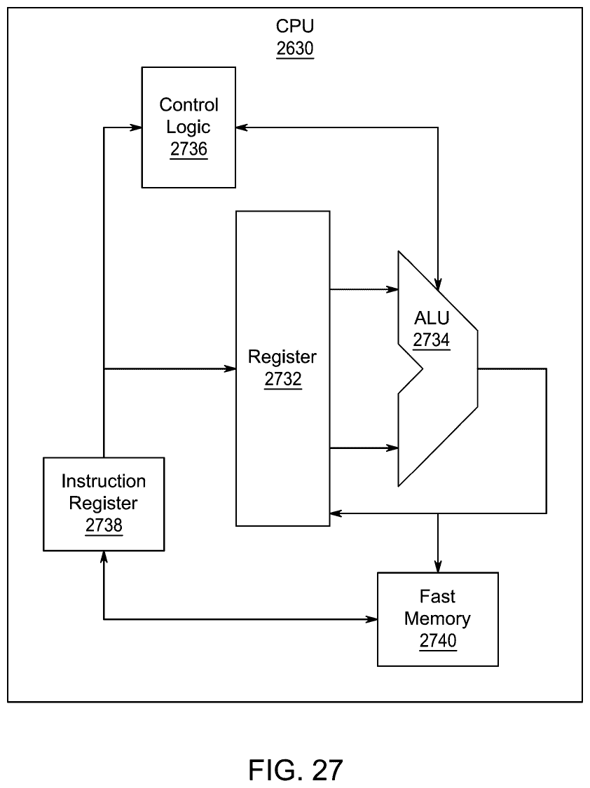

For example, FIG. 27 shows one implementation of the CPU 2630. In one implementation, an instruction register 2738 retrieves instructions from a fast memory 2740. At least part of these instructions is fetched from the instruction register 2738 by a control logic 2736 and interpreted according to the instruction set architecture of the CPU 2630. Part of the instructions can also be directed to a register 2732. In one implementation, the instructions are decoded according to a hardwired method, and in another implementation, the instructions are decoded according to a microprogram that translates instructions into sets of CPU configuration signals that are applied sequentially over multiple clock pulses. After fetching and decoding the instructions, the instructions are executed using an Arithmetic Logic Unit (ALU) 2734 that loads values from the register 2732 and performs logical and mathematical operations on the loaded values according to the instructions. The results from these operations can be feedback into the register 2732 and/or stored in the fast memory 2740. According to certain implementations, the instruction set architecture of the CPU 2630 can use a reduced instruction set architecture, a complex instruction set architecture, a vector processor architecture, a very large instruction word architecture. Furthermore, the CPU 2630 can be based on a Von Neuman model or a Harvard model. The CPU 2730 can be a digital signal processor, an FPGA, an ASIC, a Programmable Logic Array (PLA), a PLD, or a Complex Programmable Logic Device (CPLD). Further, the CPU 2630 can be an x86 processor by the Intel or by the AMD; an Advanced Reduced Instruction Set Computing (RISC) Machine (ARM) processor, a power architecture processor by, e.g., an International Business Machines Corporation (IBM); a Scalable Processor Architecture (SPARC) processor by Sun Microsystems or by Oracle; or other known CPU architecture.

Referring again to FIG. 26, the data processing system 2600 can include that the SB/ICH 2620 is coupled through a system bus to an I/O Bus, a ROM 2656, a Universal Serial Bus (USB) port 2664, a flash binary I/O system (BIOS) 2668, and a graphics controller 2658. PCI/PCIe devices can also be coupled to a SB/ICH 2688 through a PCI bus 2662.

The PCI devices may include, for example, Ethernet adapters, add-in cards, and PC cards for notebook computers. The HDD 2660 and an optical drive 2666 (e.g., CD-ROM) can use, for example, an Integrated Drive Electronics (IDE) or a Serial Advanced Technology Attachment (SATA) interface. In one implementation, the I/O bus can include a super I/O (SIO) device.

Further, the HDD 2660 and the optical drive 2666 can also be coupled to the SB/ICH 2620 through a system bus. In one implementation, a keyboard 2670, a mouse 2672, a parallel port 2678, and a serial port 2676 can be connected to the system bus through the I/O bus. Other peripherals and devices that can be connected to the SB/ICH 2620 using a mass storage controller such as a SATA or a Parallel Advanced Technology Attachment (PATA), an Ethernet port, an ISA bus, a Low Pin Count (LPC) bridge, a System Management (SM) bus, a Direct Memory Access (DMA) controller, and an Audio Compressor/Decompressor (Codec).

Moreover, the present disclosure is not limited to the specific circuit elements described herein, nor is the present disclosure limited to the specific sizing and classification of these elements. For example, the skilled artisan will appreciate that the circuitry described herein may be adapted based on changes on battery sizing and chemistry or based on the requirements of the intended back-up load to be powered.

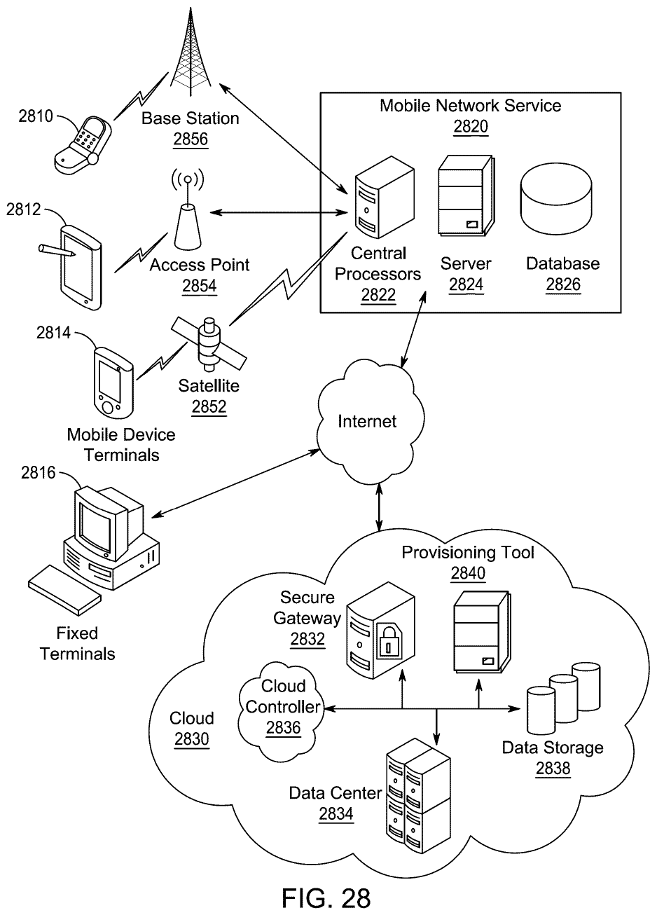

The functions and features described herein may also be executed by various distributed components of a system. For example, one or more processors may execute these system functions, wherein the processors are distributed across multiple components communicating in a network. The distributed components may include one or more client and server machines, which may share processing, as shown by FIG. 28, in addition to various human interface and communication devices (e.g., display monitors, smart phones, tablets, Personal Digital Assistants (PDAs)). More specifically, FIG. 28 illustrates client devices, including a smartphone 2811, a tablet 2812, a mobile device terminal 2814 and fixed terminals 2816. These client devices may be commutatively coupled with a mobile network service 2820 via a base station 2856, an access point 2854, a satellite 2852 or via an internet connection. The mobile network service 2820 may comprise central processors 2822, a server 2824 and a database 2826. The fixed terminals 2816 and the mobile network service 2820 may be commutatively coupled via an internet connection to functions in a cloud 2830 that may comprise a security gateway 2832, a data center 2834, a cloud controller 2836, a data storage 2838 and a provisioning tool 2840. The network may be a private network, such as the LAN or the WAN, or may be a public network, such as the Internet. Input to the system may be received via direct user input and received remotely either in real-time or as a batch process. Additionally, some implementations may be performed on modules or hardware not identical to those described. Accordingly, other implementations are within the scope of the present disclosure.

The above-described hardware description is a non-limiting example of corresponding structure for performing the functionality described herein.

Numerous modifications and variations of the present disclosure are possible in light of the above teachings. It is, therefore, to be understood that the invention may be practiced otherwise than as specifically described herein.

1. A portable system for inspecting an electrical equipment for partial discharge (PD), comprising:
an acoustic emission sensor for detecting a mechanical wave produced by an electrical discharge event and converting the mechanical wave into an audio signal;
a signal preprocessing unit to determine a waveform of the audio signal and converting the determined waveform into a waveform image, wherein the converting includes performing a Short-Time Fourier Transform (STFT) on the audio signal to preserve time information and further to convert the transformed audio signal into a spectrogram as the waveform image;
a processing circuitry configured with a Convolution Neural Network (CNN) that takes as input the waveform image and outputs a fault class among four different partial discharge types which are arcing, corona discharge, tracking, looseness as well as healthy equipment; and
an output device for outputting an indication of the fault class for the electrical equipment.

2. The portable system of claim 1, wherein the acoustic emission sensor is an ultrasound detector for detection of the mechanical wave produced by the electrical discharge event that travels through an insulation of the electrical equipment to a surrounding vicinity of the electrical equipment.

3. The portable system of claim 1, wherein during the electrical discharge event, the mechanical wave is generated within a solid material of the electrical equipment and travels through different materials until it reaches the acoustic emission sensor made of piezoelectric ceramic.

4. The portable system of claim 1, wherein the signal preprocessing unit performs Short-Time Fourier Transform including breaking the audio signal into segments and taking Fast Fourier Transform (FFT) of each segment.

5. The portable system of claim 4, wherein the signal processing unit constructs the segments into a spectrogram.

6. The portable system of claim 1, wherein the signal preprocessing unit converts the transformed signal into a spectrogram by extracting Mel-frequency cepstral coefficients (MFCC) that represent short-term power spectrum of sound.

7. The portable system of claim 6, wherein the signal preprocessing unit concatenates features extracted from the STFT and the MFCCs into a matrix, and the matrix is transformed into the waveform image, and
the waveform image is provided as an input to the CNN.

8. The portable system of claim 6, wherein the signal preprocessing unit concatenates the MFCCs over time to create a feature vector for each audio segment.

9. The portable system of claim 8, wherein the signal processing unit converts the feature vector into the waveform image.

10. The portable system of claim 9, wherein the CNN takes as the input the waveform image and is trained to determine the fault class among the four different PD types which are the arcing, the corona discharge, the tracking, the looseness, as well as the healthy equipment by distinguishing between audio signals.

11. A method for classifying Partial Discharge (PD) in an electrical equipment, comprising:
detecting, by an acoustic emission sensor, a mechanical wave produced by an electrical discharge event and converting the mechanical wave into an audio signal;
determining, by a signal preprocessing unit, a waveform of the audio signal and converting the determined waveform into a waveform image, wherein the converting includes performing a Short-Time Fourier Transform (STFT) on the audio signal to preserve time information and further to convert the audio signal into a spectrogram as the waveform image;
predicting, by a processing circuitry configured with a Convolution Neural Network (CNN) that takes as input the waveform image, a fault class among four different PD types which are an arcing, a corona discharge, a tracking, a looseness, as well as a healthy equipment; and
outputting, by an output device, an indication of the fault class of the electrical equipment.

12. The method of claim 11, wherein the detection of the mechanical wave is performed by an ultrasound detector that detects the mechanical wave that travels through an insulation of the electrical equipment to a surrounding vicinity of the electrical equipment.

13. The method of claim 11, wherein the electrical discharge event generates the mechanical wave within a solid material of the electrical equipment and the mechanical wave travels through different materials until it reaches the acoustic emission sensor made of piezoelectric ceramic.

14. The method of claim 11, further comprising performing, by the signal preprocessing unit, the STFT in which the audio signal is divided into audio segments and a Fast Fourier Transform (FFT) is taken of each audio segment.

15. The method of claim 14, further comprising constructing, by the signal processing unit, the audio segments into the spectrogram.

16. The method of claim 11, further comprising converting, by the signal preprocessing unit, the audio signal into the spectrogram by extracting Mel-Frequency Cepstral Coefficients (MFCCs) that represent a short-term power spectrum of sound.

17. The method of claim 16, further comprising:
concatenating, by the signal preprocessing unit, features extracted from the STFT and the MFCCs into a matrix, and the matrix is transformed into the waveform image;
inputting the waveform image to the CNN, and
determining, by the CNN, the fault class among the four different PD types which are the arcing, the corona discharge, the tracking, the looseness, as well as the healthy equipment, by distinguishing between audio signals.

18. The method of claim 16, further comprising concatenating, by the signal preprocessing unit, the MFCCs over time to create a feature vector for each audio segment.

19. The method of claim 18, further comprising converting, by the signal processing unit, the feature vector into the waveform image.

20. A non-transitory computer-readable medium having instructions stored therein that, when executed by one or more processors, cause the one or more processors to perform a method for classifying Partial Discharge (PD) in an electrical equipment, comprising:
detecting, by an acoustic emission sensor, a mechanical wave produced by an electrical discharge event and converting the mechanical wave into an audio signal;
determining, by a signal preprocessing unit, a waveform of the audio signal and converting the determined waveform into a waveform image, wherein the converting includes performing a Short-Time Fourier Transform (STFT) on the audio signal to preserve time information and further to convert the audio signal into a spectrogram as the waveform image;
predicting, by a processing circuitry configured with a Convolution Neural Network (CNN) that takes as input the waveform image, a fault class among four different PD types, which are an arcing, a corona discharge, a tracking, a looseness as well as a healthy equipment; and
outputting, by an output device, an indication of the fault class of the electrical equipment.
